(19) United States
(12) Patent Application Publication
(10) Pub. No.: US 2012/0223392 A1
(43) Pub. Date: Sep. 6, 2012

(54) SEMICONDUCTOR DEVICE

(75) Inventor: Hirokazu OKADA, Yokohama (JP)

(73) Assignee: FUJITSU SEMICONDUCTOR LIMITED, Yokohama-shi (JP)

(21) Appl. No.: 13/368,892

(22) Filed: Feb. 8, 2012

(30) Foreign Application Priority Data
Mar. 1, 2011 (JP) 2011-043738

(51) Int. Cl. H01L 27/092

(52) U.S. Cl. 257/369; 257/E27.062

(57) ABSTRACT

A semiconductor device includes a first device region formed over a semiconductor substrate and defined by a device isolation region, a first transistor including a first gate electrode formed over the first device region, a first source region formed in the first device region on a first side of the gate electrode, and a first drain region formed in the first device region on a second side of the first gate electrode, a first pattern formed over the device isolation region on the first side of the first gate electrode in parallel with the first gate electrode, and a first conductor plug connected to the first source region. The first conductor plug is electrically connected to one of a ground line and a power source line, and the first pattern is electrically connected to the other of the ground line and the power source line.

### CROSS-REFERENCE TO RELATED APPLICATION

This application is based upon and claims the benefit of priority of the prior Japanese Patent Application No. 2011-43738, filed on Mar. 1, 2011, the entire contents of which are incorporated herein by reference.

### FIELD

The embodiments discussed herein are related to a semiconductor device.

### BACKGROUND

Recently, in digital LSI circuits (Large Scale Integrated circuits), etc. represented by microprocessors, the operation speed increase and lower power consumption are being mad.

To stably operate an LSI at low voltages in the high frequency range of the GHz band, it is important to suppress the power source voltage variation due to rapid changes of the load impedance of the LSI and to remove high frequency noises of the power source.

Conventionally, by providing decoupling capacitors in a semiconductor device, for example, the power source voltage variation is suppressed, and the high frequency noises are removed.

Related references are as follows:
Japanese Laid-open Patent Publication No. 2005-167039; and
Japanese Laid-open Patent Publication No. 2008-235350.

### SUMMARY

According to aspects of an embodiment, a semiconductor device comprising: a first device region formed in a semiconductor substrate and defined by a device isolation region; a first transistor of a first conduction type including a first gate electrode formed over the first device region, a first source region formed in the first device region on a first side of the first gate electrode, and a first drain region formed in the first device region on a second side of the first gate electrode; a first pattern formed over the device isolation region on the first side of the first gate electrode in parallel with the first gate electrode; an insulation layer formed over the semiconductor substrate, covering the first transistor and the first pattern; and a first conductor plug buried in a first contact hole down to the first source region, wherein the first conductor plug being electrically connected to one of a ground line and a power source line, and the first pattern being electrically connected to the other of the ground line and the power source line.

The object and advantages of the embodiments will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIG. 1 is a plan view of the semiconductor device according to a first embodiment;

FIG. 2 is a circuit diagram of the unit cell of the semiconductor device according to the first embodiment;

FIGS. 3A to 3D are sectional views of the semiconductor device according to the first embodiment (Part 1);

FIGS. 4A to 4D are sectional views of the semiconductor device according to the first embodiment (Part 2);

FIGS. 5A to 14D are sectional views of the semiconductor device according to the first embodiment in the steps of the method for manufacturing the semiconductor device, which illustrate the method;

FIG. 15 is a plan view of the semiconductor device according to a second embodiment, which illustrates the structure;

FIGS. 16A to 16D are sectional views of the semiconductor device according to the second embodiment (Part 1);

FIGS. 17A to 17D are sectional views of the semiconductor device according to the second embodiment (Part 2);

FIG. 18 is a plan view of the semiconductor device according to a third embodiment;

FIGS. 19A to 19D are sectional views of the semiconductor device according to the third embodiment (Part 1);

FIGS. 20A to 20D are sectional views of the semiconductor device according to the third embodiment (Part 2);

FIG. 21 is a plan view of the semiconductor device according to a fourth embodiment;

FIGS. 22A to 22D are sectional view of the semiconductor device according to the fourth embodiment (Part 1);

FIGS. 23A to 23D are sectional view of the semiconductor device according to the fourth embodiment (Part 2);

FIG. 24 is a plan view of the semiconductor device according to a fifth embodiment;

FIGS. 25A to 25D are sectional views of the semiconductor device according to the fifth embodiment (Part 1);

FIGS. 26A to 26D are sectional views of the semiconductor device according to the fifth embodiment (Part 2);

FIG. 27 is a plan view of the semiconductor device according to a sixth embodiment;

FIGS. 28A to 28D are sectional views of the semiconductor device according to the sixth embodiment (Part 1);

FIGS. 29A to 29D are sectional views of the semiconductor device according to the sixth embodiment (Part 2);

FIG. 30 is a plan view of the semiconductor device according to a seventh embodiment;

FIGS. 31A to 31D are sectional views of the semiconductor device according to the seventh embodiment (Part 1);

FIGS. 32A to 32D are sectional views of the semiconductor device according to the seventh embodiment (Part 2);

FIG. 33 is a plan view of the semiconductor device according to an eighth embodiment; and

FIG. 34 is a plan view of the semiconductor device according to a ninth embodiment.

### DESCRIPTION OF EMBODIMENTS

The provision of a decoupling capacitor in a semiconductor device is a factor blocking the downsizing, etc. of the semiconductor device.

Preferred embodiments of the present invention will be explained with reference to accompanying drawings.

### [a] First Embodiment

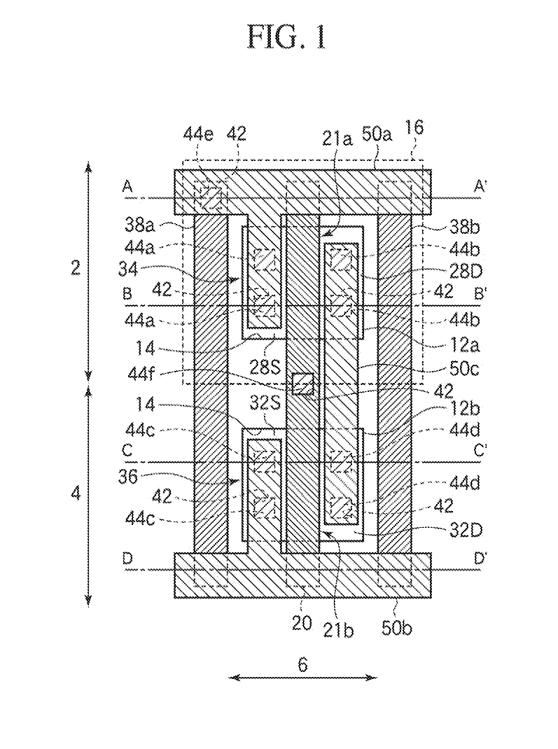

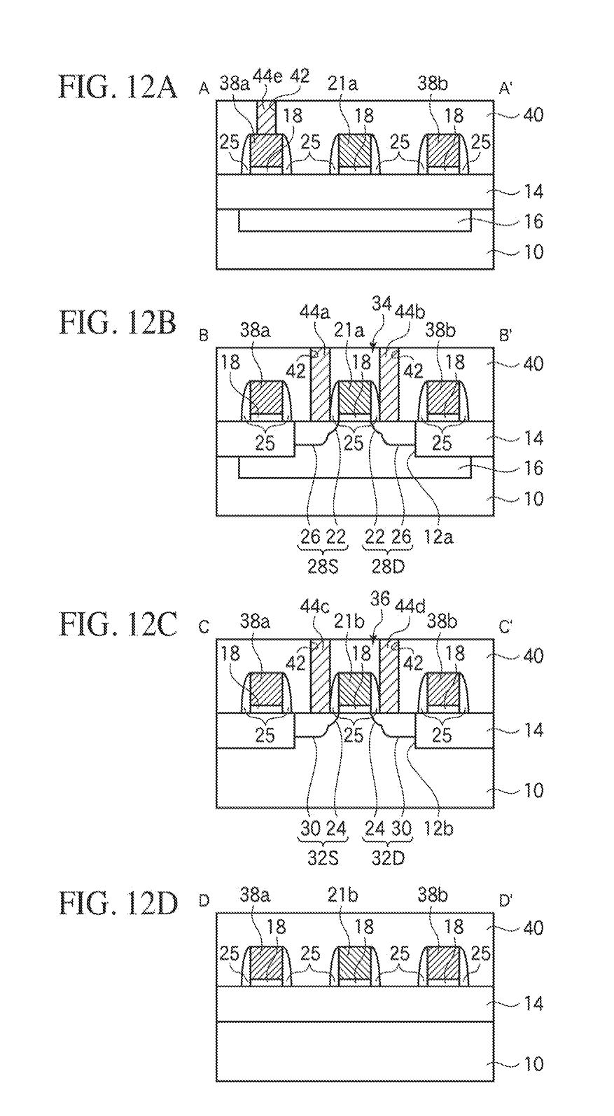

The semiconductor device according to a first embodiment and its manufacturing method will be described with reference to FIGS. 1 to 14D.

(Semiconductor Device)

First, the semiconductor device according to the present embodiment will be described with reference to FIGS. 1 to 4D.

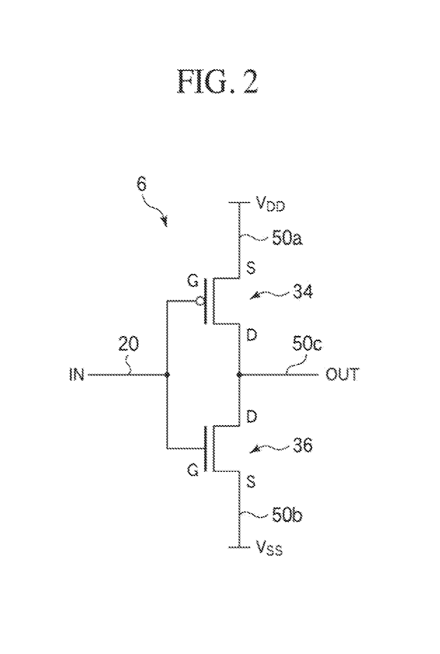

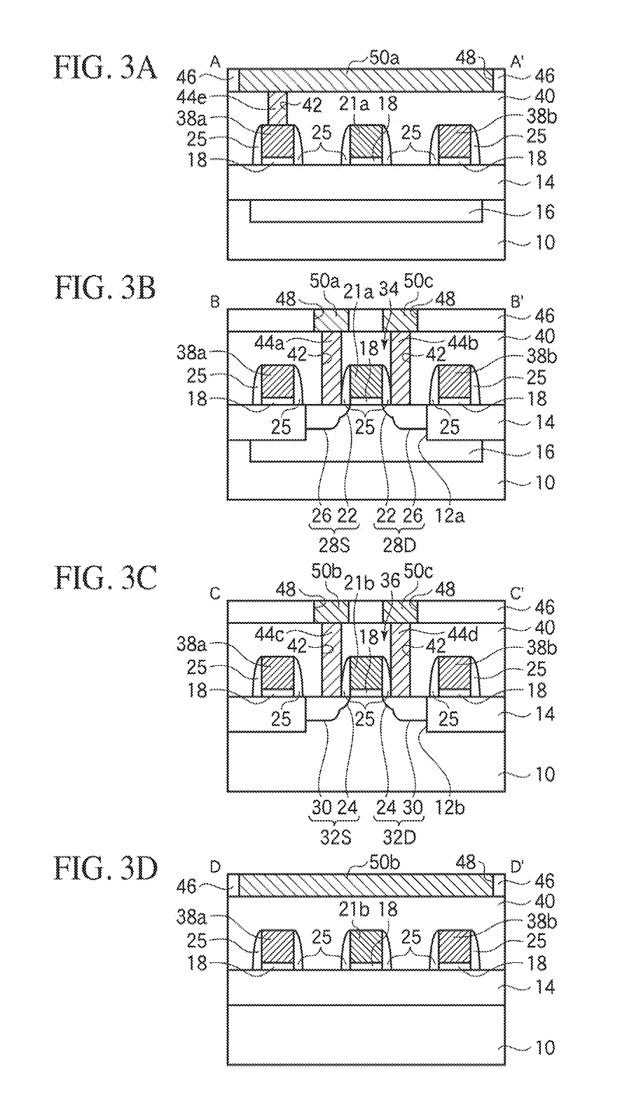

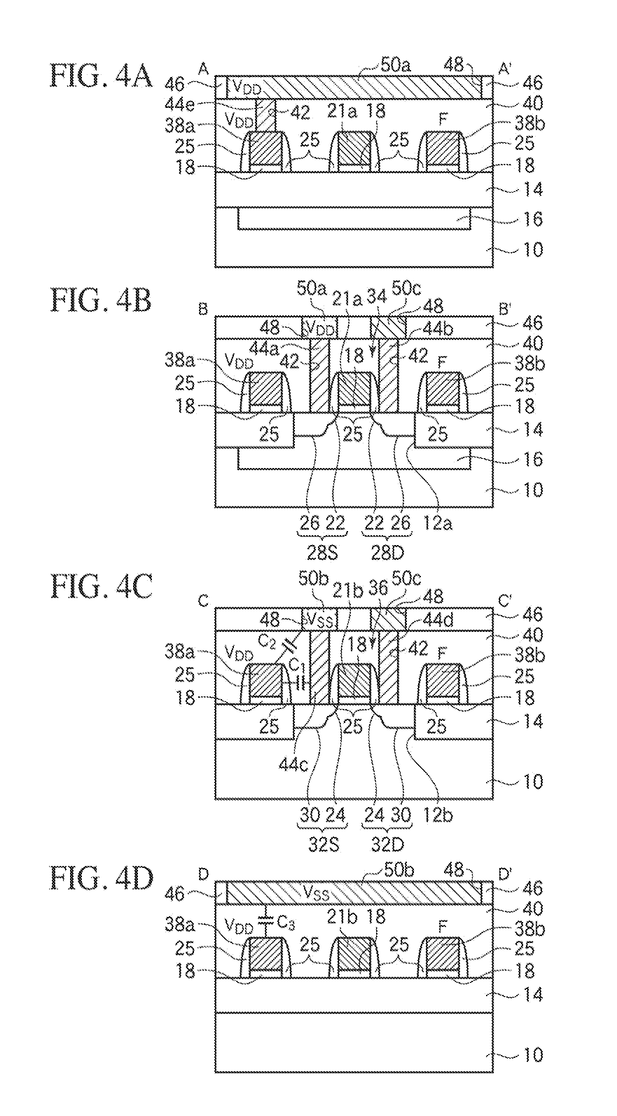

FIG. 1 is a plan view of the semiconductor device according to the present embodiment. The upper part of the drawing of FIG. 1 is the region where a PMOS transistor is formed (PMOS transistor formed region) 2. The lower part of the drawing of FIG. 1 is the region where an NMOS transistor is formed (NMOS transistor formed region) 4. FIG. 2 is the circuit diagram of the unit cell of the semiconductor device according to the present embodiment. FIGS. 3A to 3D are sectional views (Part 1) of the semiconductor device according to the present embodiment. FIGS. 4A to 4D are sectional views (Part 2) of the semiconductor device according to the present embodiment. FIG. 3A and FIG. 4A correspond to the A-A′ line section in FIG. 1. FIG. 3B and FIG. 4B correspond to the B-B′ line section in FIG. 1. FIG. 3C and FIG. 4C correspond to the C-C′ line section in FIG. 1. FIG. 3D and FIG. 4D correspond to the D-D′ line section in FIG. 1.

The semiconductor device according to the present embodiment includes a large number of unit cells 6, but FIG. 1 illustrates one of the unit cells 6.

The semiconductor device according to the present embodiment will be described here by means of the example that the unit cell 6 is a CMOS inverter circuit including a PMOS transistor 34 and an NMOS transistor 36.

As illustrated in FIG. 2, the unit cell 6 of the present embodiment includes the PMOS transistor 34 and the NMOS transistor 36.

The source of the PMOS transistor 34 is connected to a power source potential VDD via a power source line 50a.

The drain of the PMOS transistor 34 and the drain of the NMOS transistor 36 are electrically connected.

The source of the NMOS transistor 36 is connected to a ground potential VSS via a ground line 50b.

An input voltage IN is applied to the gate of the PMOS transistor 34 and the gate of the NMOS transistor 36.

An output signal line 50c is connected to the drain of the PMOS transistor 34 and the drain of the NMOS transistor 36.

As illustrated in FIGS. 1 and 3A to 3D, a device isolation regions 14 defining device regions (active regions) 12a, 12b are formed in a semiconductor substrate 10. The semiconductor substrate 10 is, e.g., a P-type silicon substrate. The device isolation regions 14 are formed of, e.g., silicon dioxide. The device region 12a is formed in the PMOS transistor formed region 2. The device region 12b is formed in the NMOS transistor formed region 4.

In the semiconductor substrate 10 in the PMOS transistor formed region 2, an N-type well 16 is formed.

On the semiconductor substrate 10 in the PMOS transistor formed region 2, a gate electrode 21a is formed with a gate insulation film 18 formed therebetween. On the semiconductor substrate 10 in the NMOS transistor formed region 4, a gate electrode 21b is formed with the gate insulation film 18 formed therebetween.

The gate electrode 21a and the gate electrode 21b are parts of a gate interconnection 20 continuously formed in the PMOS transistor formed region 2 and the NMOS transistor formed region 4. The gate interconnection 20 is formed of, e.g., polysilicon film or others. The width of the gale line 20 is, e.g., about 30 nm. The height of the gate interconnection 20 is, e.g., about 80 nm.

In the gate interconnection 20 in the PMOS transistor formed region 2, a P-type dopant impurity is implanted, whereby the gate electrode 21a of the PMOS transistor 34 is formed. In the gate interconnection 20 in the NMOS transistor formed region 4, an N-type dopant impurity is implanted, whereby the gate electrode 21b of the NMOS transistor 36 is formed. The gate interconnection 20 crosses the device regions 12a, 12b.

In the device region 12a on both sides of the gate electrode 21a of the PMOS transistor 34, lightly doped impurity regions (extension regions) 22 forming the shallow regions of the extension source/drain structure are formed.

In the device region 12b on both sides of the gate electrode 21b of the NMOS transistor 36, lightly doped impurity regions (extension regions) 24 forming the shallow regions of the extension source/drain structure are formed.

On the side wall of the gate interconnection 20, a sidewall insulation film 25 is formed.

In the device region 12a on both sides of the gate electrode 21a of the PMOS transistor 34 with the sidewall insulation film 25 formed on, heavily doped impurity regions 26 forming the deep regions of the extension source/drain structure are formed.

The lightly doped impurity region 22 and the heavily doped impurity regions 26 form the source/drain regions 28S, 28D of the PMOS transistor 34. The source region 28S is formed on one side of the gate electrode 21a of the PMOS transistor 34, i.e., in the device region 12a on the left side of the drawing of FIG. 1. The drain region 28D is formed on the other side of the gate electrode 21a of the PMOS transistor 34, i.e., in the device region 12a on the right side of the drawing of FIG. 1.

In the device region 12b on both sides of the gate electrode 21b of the NMOS transistor 36 with the sidewall insulation film 25 formed on, heavily doped impurity regions 30 forming the deep regions of the extension source/drain structure.

The lightly doped impurity regions 24 and the heavily doped impurity regions 30 form the source/drain regions 32S, 32D of the NMOS transistor 36. The source region 32S is formed on one side of the gate electrode 21b of the NMOS transistor 36, i.e., in the device region 12b on the left side of the drawing of FIG. 1. The drain region 32D is formed on the other side of the gate electrode 21b of the NMOS transistor 36, i.e., in the device region 12b on the right side of the drawing of FIG. 1.

Thus, the PMOS transistor 34 including the gate electrode 21a and the source/drain regions 28S, 28D is formed. The NMOS transistor 36 including the gate electrode 21b and the source/drain regions 32S, 32D is formed.

At the upper part of the gate electrodes 21a, 21b and on the source/drain regions 28S, 28D, 32S, 32D, silicide layers (not illustrated) are respectively formed. The silicide layers are, e.g., nickel silicide layer, cobalt silicide layer or others.

On one side of the gate interconnection 20, i.e., on the device isolation region 14 on the left side of the drawing of FIG. 1, a dummy gate interconnection (a dummy gate electrode, a dummy gate pattern, a dummy pattern, a pattern) 38a is formed in parallel with the gate interconnection 20. The dummy gate interconnection 38a is positioned on the left side of the device regions 12a, 12b in the drawing.

On the other side of the gate interconnection 20, i.e., on the device isolation region 14 on the right side of the drawing of FIG. 1, a dummy gate interconnection (a dummy gate electrode, a dummy gate pattern, a dummy pattern a pattern) 38b is formed in parallel with the gate interconnection 20. The dummy gate interconnection 38b is positioned on the right side of the device regions 12a, 12b in the drawing.

The dummy gate interconnections 38a, 38b are formed of, e.g., polysilicon film. In the dummy gate interconnections 38a, 38b in the PMOS transistor formed region 2, a P-type dopant impurity, for example, is implanted. In the dummy gate electrodes 38a, 38b in the NMOS transistor formed region 4, an N-type dopant impurity, for example, is implanted. The width of the dummy gate interconnections 38a, 38b is, e.g., about 80 nm. The height of the dummy gate interconnections 38a, 38b is, e.g., about 80 nm. The space between the gate interconnection 20, and the dummy gate interconnections 38a, 38b is, e.g., about 100 nm.

The sidewall insulation film 25 is formed also on the side walls of the dummy gate electrodes 38a, 38b.

The dummy gate interconnections 38a, 38b are originally for decreasing the scatter of the processed dimensions of the gate interconnections (gate electrodes) 20. In the present embodiment, the dummy gate interconnections 38a are used not only for decreasing the scatter of the processed dimensions of the gate interconnection 20 but also for forming a decoupling capacitor as will be described later.

The dummy gate interconnections 38a, 38b and the gate interconnection 20 are formed by patterning one and the same polysilicon film.

On the semiconductor substrate 10 with the PMOS transistor 34, the NMOS transistor 36 and the dummy gate electrodes 38a, 38b formed on, an inter-layer insulation film 40 of a silicon oxide film of, e.g., a 200 nm-film thickness is formed.

The inter-layer insulation film 40 may be porous low-dielectric constant film or others.

In the inter-layer insulation film 40, contact holes 42 down to the source/drain regions 28S, 28D of the PMOS transistor 34, and contact holes 42 down to the source/drain regions 32S, 32D of the NMOS transistor 36 are respectively formed. In the inter-layer insulation film 40, a contact hole 42 down to the dummy gate interconnection 38a is formed. In the inter-layer insulation film 40, a contact hole 42 down to the gate interconnection 20 on the border between the PMOS transistor formed region 2 and the NMOS transistor formed region 4. The diameter of the contact holes 42 is, e.g., about 50 nm.

In the contact holes 42, a barrier metal film (not illustrated), for example, is formed. The barrier metal film is the layer film, e.g., of Ti film (not illustrated) and TiN film (not illustrated).

In the contact holes 42 with the barrier metal film formed in, conductor plugs 44a-44f of, e.g., tungsten (W) are buried in. The conductor plug 44a is connected to the source regions 28S of the PMOS transistor 34. The conductor plug 44b is connected to the drain region 28D of the PMOS transistor 34. The conductor plug 44c is connected to the source region 32S of the NMOS transistor 36. The conductor plug 44d is connected to the drain region 32D of the NMOS transistor 36. The conductor plug 44e is connected to the dummy gate interconnection 38a. The conductor plug 44f is connected to the gate interconnection 20. The space between the conductor plugs 44a-44d and the dummy gate interconnections 38a, 38b is, e.g., about 30 nm. The space between the conductor plugs 44a-44d and the gate interconnection 20 is, e.g., about 30 nm.

On the inter-layer insulation film 40 with the conductor plugs 44a-44f buried in, an inter-layer insulation film 46 of a silicon oxide film of, e.g., an about 100 nm-film thickness is formed.

In the inter-layer insulation film 46, trenches 48 for interconnections to be buried in are formed.

In the trenches 48, a barrier metal film (not illustrated), for example, is formed. The barrier metal film is, e.g., Ta (tantalum) film.

In the trenches 48 with the barrier metal film buried in, lines 50a-50c of, e.g., Cu (copper), more specifically, a power source line 50a, the ground line 50b and a signal line 50c are buried in. The width of the lines 50a-50c is about, e.g., about 50 nm.

The power source line 50a is electrically connected to the source region 28S of the PMOS transistor 34 via the conductor plug 44a. The power source line 50a is electrically connected to the dummy gate electrode 38a via the conductor plug 44e. The power source line 50a is to be connected to, e.g., the power source potential VDD (see FIGS. 2 and 4A to 4D).

The ground line 50b is electrically connected to the source region 32S of the NMOS transistor 36 via the conductor plug 44c. One part of the ground line 50b is formed in parallel with the dummy gate interconnection 38a. Another part of the ground line 50b crosses the dummy gate interconnection 38a. The ground line 50b is to be connected to, e.g., a ground potential VSS (see FIGS. 2 and 4A to 4D).

The signal line 50c is electrically connected to the drain region 28D of the PMOS transistor 34 via the conductor plug 44b and electrically connected to the drain region 32D of the NMOS transistor 36 via the conductor plug 44d.

The dummy gate interconnection 38b positioned on the right side of the gate interconnection 20 in the drawing is electrically floating.

In the present embodiment, the dummy gate interconnection 38b is electrically floating for the following reason.

That is, the conductor plugs 44b, 44d connected to the drain regions 28D, 32D are connected to the signal line 50c. In the case that the dummy gate interconnection 38b adjacent to the conductor plugs 44b, 44d is connected to the power source potential VDD and the ground potential VSS, the conductor plugs 44b, 44d capacitively-coupled with the dummy gate electrode 38b, which causes signal delay. Then, in the present embodiment, to prevent such signal delay, the dummy gate interconnection 38b adjacent to the conductor plugs 44b, 44d connected to the drain regions 28D, 32D is electrically floating.

Thus, the semiconductor device according to the present embodiment is formed.

According to the present embodiment, the dummy gate interconnection 38a is connected to the power source potential VDD while the conductor plug 44c connected to the source region 32S of the NMOS transistor 36 is connected to the ground potential VSS. Thus, according to the present embodiment, a decoupling capacitance C1 can be obtained between the dummy gate interconnection 38a and the conductor plug 44c (see FIGS. 4A to 4D).

According to the present embodiment, the dummy gate interconnection 38a is connected to the power source potential VDD while a part of the ground line 50b is formed in parallel with the dummy gate interconnection 38a. Thus, a decoupling capacitance C2 can be obtained between the dummy gate interconnection 38a and the ground line 50b (see FIGS. 4A to 4D).

According to the present embodiment, the dummy gate interconnection 38a is connected to the power source potential VDD while another part of the ground line 50b crosses the dummy gate interconnection 38a. Thus, a decoupling capacitance C3 can be obtained between the dummy gate electrode 38a and the ground line 50b (see FIGS. 4A to 4D).

The total value of these decoupling capacitances C1, C2, C3 is, e.g., about several tenth of a fF to several fF.

According to the present embodiment, the dummy gate electrode 38a positioned on the side of the source regions 28S, 32S of the transistors 34, 36 is connected to the power source potential VDD, and the source region 32S is connected to the ground potential VSS. Thus, according to the present embodiment, a decoupling capacitance can be formed in the unit cell 6. According to the present embodiment, such decoupling capacitance is formed in each unit cell 6, which makes it unnecessary to separately provide in each unit cell 6 a decoupling capacitor of a large opposed area. If the decoupling capacitor is provided separate from the unit cell 6, the area required to form such decoupling capacitor can be small. Thus, according to the present embodiment, the downsized semiconductor device can be manufactured.

Furthermore, according to the present embodiment, the dummy gate interconnection 38b positioned on the side of the drain regions 28D, 32D of the transistors 34, 36 is electrically floating. Thus, the conductor plugs 44b, 44d connected to the drain regions 28D, 32D are prevented from capacitive coupling with the dummy gate interconnection 38b. Thus, according to the present embodiment, signal delay in the signal line 50c electrically connected to the drain regions 28D, 32D can be prevented.

(Method for Manufacturing the Semiconductor Device)

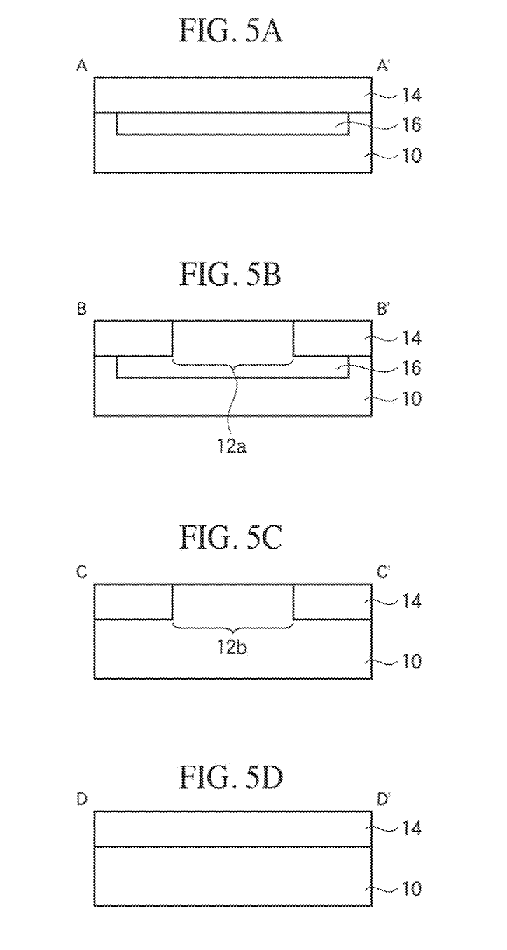

Next, the method for manufacturing the semiconductor device according to the present embodiment will be described with reference to FIGS. 5A to 14D. FIGS. 5 to 14D are sectional views of the semiconductor device according to the present embodiment in the steps of the method for manufacturing the semiconductor device, which illustrate the method. FIGS. 5A, 6A, 7A, 8A, 9A, 10A, 11A, 12A, 13A and 14A correspond to the A-A′ line section of FIG. 1. FIGS. 5B, 6B, 7B, 8B, 9B, 10B, 11B, 12B, 13B and 14B correspond to the B-B′ line section of FIG. 1. FIGS. 5C, 6C, 7C, 8C, 9C, 10C, 11C, 12C, 13C and 14C correspond to the C-C′ line section of FIG. 1. FIGS. 5D, 6D, 7D, 8D, 9D, 10D, 11D, 12D, 13D and 14D correspond to the D-D′ line section of FIG. 1.

First, as illustrated in FIGS. 5A to 5D, the device isolation regions 14 defining the device regions 12a, 12b are formed in the semiconductor substrate 10 by, e.g., STI (Shallow Trench Isolation). The semiconductor substrate 10 is, e.g., a P-type silicon substrate. Thus, in the PMOS transistor-to-be-formed region 2 and the NMOS transistor-to-be-formed region 4, the device regions 12a, 12b defined by the device isolation regions 14 are respectively formed.

Next, on the entire surface, a photoresist film (not illustrated) is formed by, e.g., spin coating.

Then, by photolithography, an opening (not illustrated) exposing the PMOS transistor-to-be-formed region 2 is formed.

Next, with the photoresist film as the mask, an N-type dopant impurity is implanted into the semiconductor substrate 10 by, e.g., ion implantation. Thus, the N-type well 16 is formed in the semiconductor substrate 10 in the PMOS transistor-to-be-formed region 2.

Then, the photoresist film is removed by, e.g., asking.

Next, the gate insulation film 18 of, e.g., silicon oxide film is formed on the surface of the semiconductor substrate 10 by, e.g., thermal oxidation.

Then, a polysilicon film is formed on the entire surface by, e.g., CVD (Chemical Vapor Deposition). The polysilicon film is to be the gate interconnection 20 and the dummy gate interconnections 38a, 38b.

Then, a photoresist film (not illustrated) is formed on the entire surface by, e.g., spin coating.

Next, by photolithography, the photoresist film is patterned into the plane shape of the gate interconnection 20 and the plane shapes of the dummy gate interconnections 38a, 38b.

Next, the polysilicon film is etched with the photoresist film as the mask. Thus, in the PMOS transistor-to-be-formed region 2 and the NMOS transistor-to-be-formed region 4, the gate interconnection 20 of polysilicon film (see FIG. 1) is continuously formed. The gate interconnection 20 includes the gate electrode 21a of the PMOS transistor 34 and the gate electrode 21b of the NMOS transistor 36. The gate interconnection 20 is formed, crossing the device regions 12a, 12b. On the device isolation region 14, the dummy gate interconnections 38a, 38b are formed in parallel with the gate interconnection 20. The dummy gate interconnection 38a formed on one side of the gate interconnection 20, i.e., on the left side of the drawing in FIG. 1 is positioned lefter than the device isolation regions 12a, 12b as viewed in the drawing. The dummy gate interconnection 38b formed on the other side of the gate interconnection 20, i.e., the right side of the drawing in FIG. 1 is positioned righter than the device isolation regions 12a, 12b as viewed in the drawing.

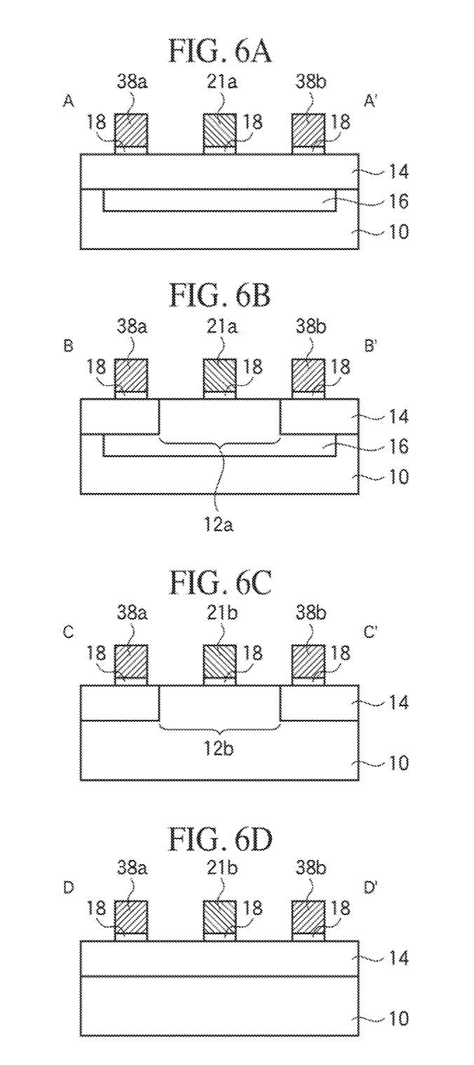

Hereafter, the photoresist film is removed by, e.g., asking (see FIGS. 6A to 6D).

Next, a photoresist film (not illustrated) is formed on the entire surface by, e.g., spin coating.

Next, by photolithography, an opening exposing the PMOS transistor-to-be-formed region 2 is formed in the photoresist film.

Then, with the photoresist film and the gate electrode 21a as the mask, a P-type dopant impurity is implanted into the semiconductor substrate 10 by, e.g., ion implantation. Thus, the P-type lightly doped impurity regions (the extension regions) 22 are formed in the semiconductor substrate 10 on both sides of the gate electrode 21a in the PMOS transistor-to-be-formed region 2. At this time, the P-type dopant impurity is implanted into the gate electrode 21a, the dummy gate interconnections 38a, 38b in the PMOS transistor-to-be-formed region 2.

Then, the photoresist film is removed by, e.g., ashing.

Then, a photoresist film (not illustrated) is formed on the entire surface by, e.g., spin coating.

Then, by photolithography, an opening (not illustrated) exposing the NMOS transistor-to-be-formed region 4 is formed in the photoresist film.

Next, with the photoresist film and the gate electrode 21b as the mask, an N-type dopant impurity is implanted into the semiconductor substrate 10 by, e.g., ion implantation. Thus, the N-type lightly doped impurity regions (the extension regions) 24 are formed in the semiconductor substrate 10 on both sides of the gate electrode 21b in the NMOS transistor-to-be-formed region 4.

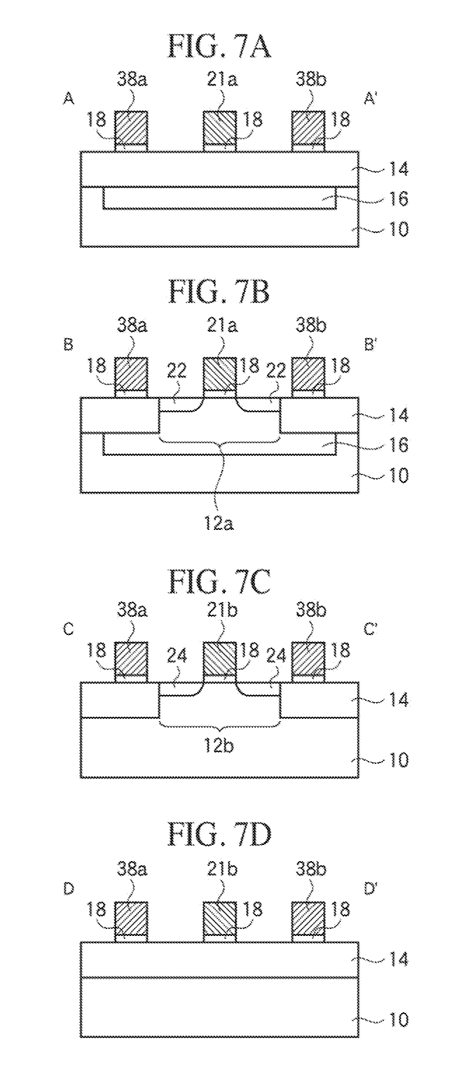

Then, the photoresist film is removed by, e.g., ashing (see FIGS. 7A to 7D).

Next, an insulation film of silicon oxide film is formed on the entire surface by, e.g., CVD.

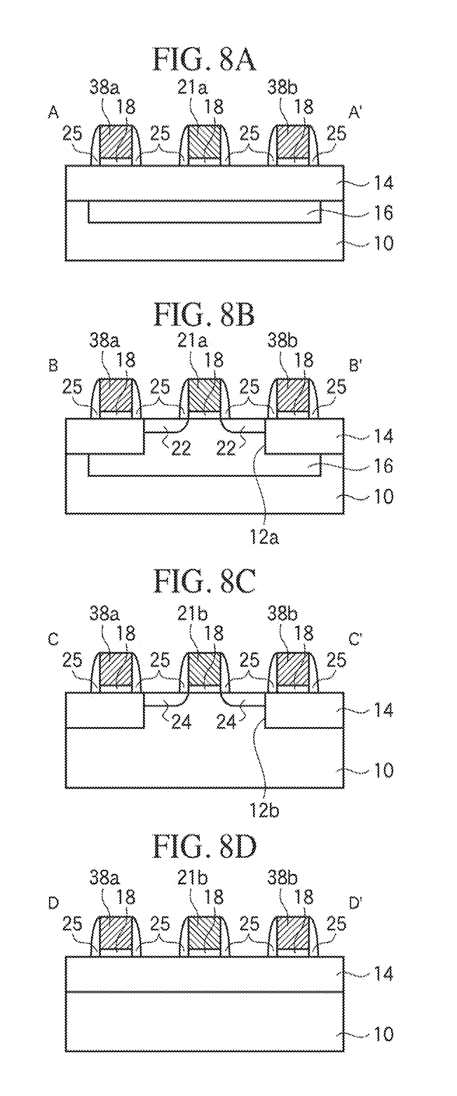

Next, the insulation film is etched by, e.g., anisotropic etching. Thus, the sidewall insulation films 25 are formed respectively on the side walls of the gate electrodes 21a, 21b and the side walls of the dummy gate interconnections 38a, 38b (see FIGS. 8A to 8D).

Next, a photoresist film (not illustrated) is formed on the entire surface by, e.g., spin coating.

Then, by photolithography, an opening (not illustrated) exposing the PMOS transistor-to-be-formed region 2 is formed.

Then, with the photoresist film, the gate electrode 21a and the sidewall insulation films 25 as the mask, a P-type dopant impurity is implanted into the semiconductor substrate 10 by, e.g., ion implantation. Thus, the P-type heavily doped impurity region 26 in the semiconductor substrate 10 on both sides of the gate electrode 21a in the PMOS transistor-to-be-formed region 2. Thus, the lightly doped impurity regions (the extension regions) 22 and the heavily doped impurity regions 26 form the source/drain regions 28S, 28D of the extension source/drain structure.

In implanting the P-type dopant impurity for forming the source/drain regions 28S, 28D, the P-type dopant impurity is implanted also in the gate electrode 21a and the dummy gate interconnections 38a, 38b in the PMOS transistor-to-be-formed region 2.

Then, the photoresist film is removed by, e.g., asking.

Next, a photoresist film (not illustrated) is formed on the entire surface by, e.g., spin coating.

Next, by photolithography, an opening (not illustrated) exposing the NMOS transistor-to-be-formed region 4 is formed in the photoresist film.

Then, with the photoresist film, the gate interconnection 20 and the sidewall insulation film 25 as the mask, an N-type dopant impurity is implanted into the semiconductor substrate 10 by, e.g., ion implantation. Thus, the N-type heavily doped impurity regions 30 are formed in the semiconductor substrate 10 on both sides of the gate interconnection 20 in the NMOS transistor-to-be-formed region 4. Thus, the lightly doped impurity regions (the extension regions) 24 and the heavily doped impurity regions 30 form the source/drain regions 32S, 32D of the extension source/drain structure.

In implanting an N-type dopant impurity for forming the source/drain regions 32S, 32D, the N-type dopant impurity is implanted also into the gate interconnection 20 and the dummy gate interconnections 38a, 38b in the NMOS transistor-to-be-formed region 4. Thus, the part of the gate interconnection 20 in the NMOS transistor-to-be-formed region 4 becomes the gate electrode 21b with the N-type dopant impurity implanted in.

Then, the photoresist film is removed by, e.g., asking.

Next, a refractory metal film (not illustrated) is formed on the entire surface.

Next, heat processing is made to react the silicon atoms in the semiconductor substrate 10 and the metal atoms in the refractory metal film with each other. Also the silicon atoms in the gate electrodes 21a, 21b and the metal atoms in the refractory metal film are reacted with each other. Also the silicon atoms in the dummy gate interconnections 38a, 38b and the metal atoms in the refractory metal film are reacted with each other.

Next, the unreacted part of the refractory metal film is etched off.

Next, heat processing is further made to accelerate the reaction between the silicon atoms in the semiconductor substrate 10 and the refractory metal atoms while accelerating the reaction between the silicon atoms in the gate electrodes 21a, 21b and the dummy gate interconnections 38a, 38b and the refractory metal atoms.

Thus, silicide films (not illustrated) are formed respectively on the source/drain regions 28S, 28D, 32S, 32D. The silicide films on the source/drain regions 28S, 28D, 32S, 32D function as the source/drain electrodes. Also on the gate electrodes 21a, 21b and on the dummy gate interconnections 28a, 28b, the silicide films (not illustrated) are formed.

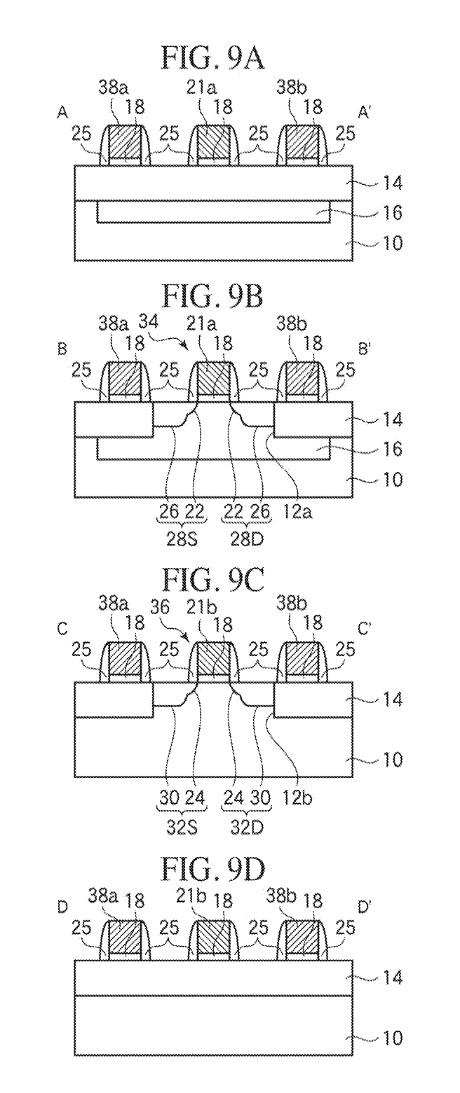

Thus, in the PMOS transistor-to-be-formed region 2, the PMOS transistor 34 including the gate electrode 21a and the source/drain regions 28S, 28D is formed. In the NMOS transistor-to-be-formed region 4, the NMOS transistor 36 including the gate electrode 21b and the source/drain regions 32S, 32D is formed (see FIGS. 9A to 9D).

Next, the inter-layer insulation film 40 of, e.g., silicon oxide film is formed on the entire surface by, e.g., CVD.

As the inter-layer insulation film 40, a porous low-dielectric constant film or others, for example, may be formed.

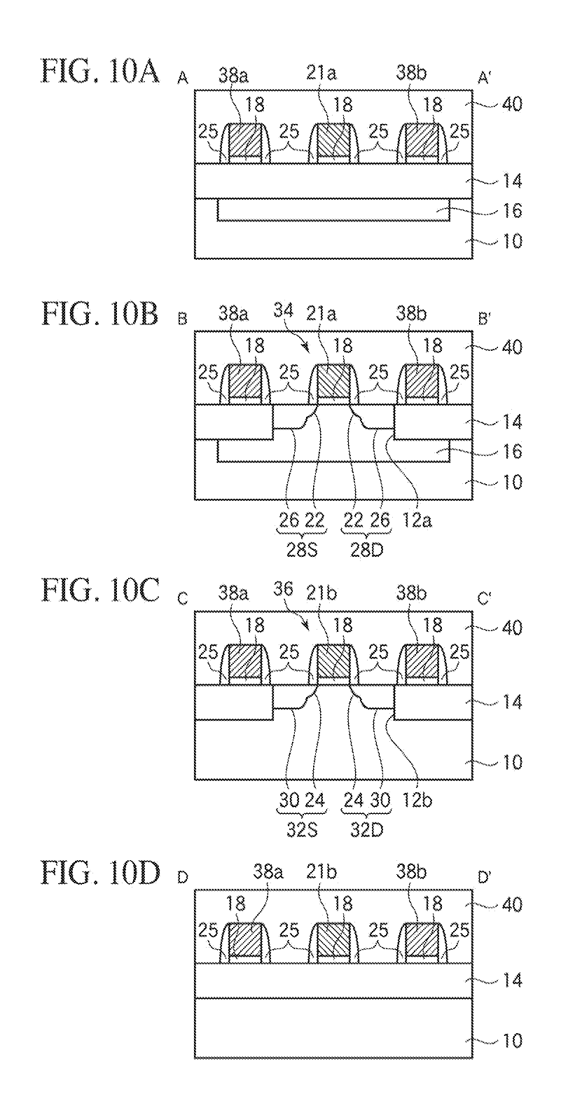

Next, the surface of the inter-layer insulation film 40 is polished by, e.g., CMP (Chemical Mechanical Polishing) (see FIGS. 10A to 10D).

Next, a photoresist film (not illustrated) is formed on the entire surface by, e.g., spin coating.

Next, by photolithography, openings (not illustrated) for forming the contact holes 42 are formed in the photoresist film.

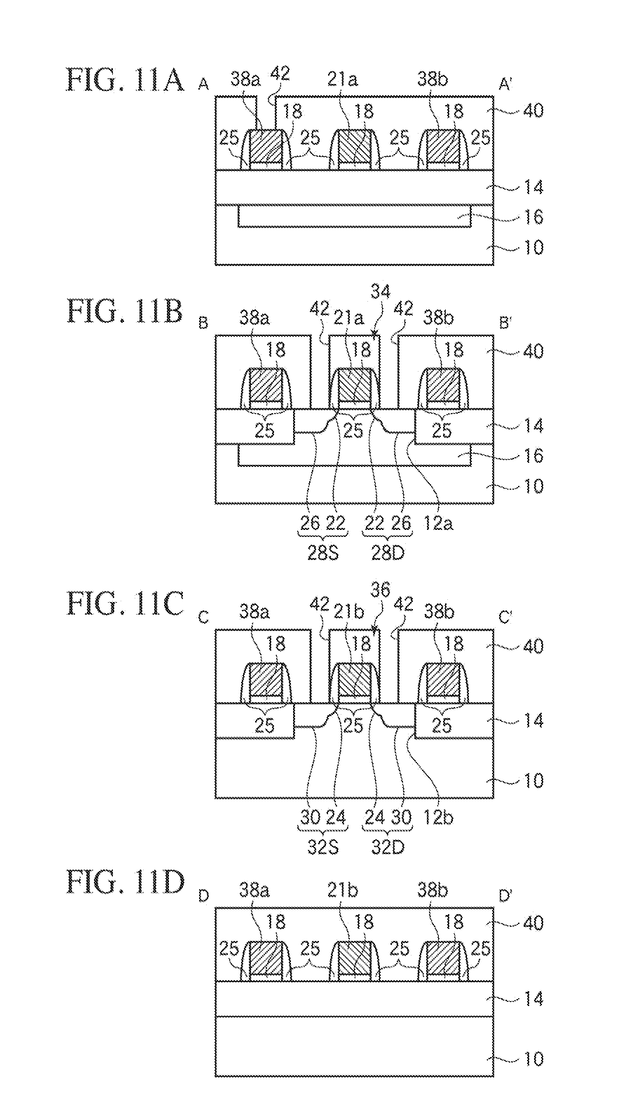

Then, with the photoresist film as the mask, the inter-layer insulation film 40 is etched. Thus, the contact holes 42 (see FIG. 1) is formed down to the gate interconnection 20 in the border between the PMOS transistor formed region 2 and the NMOS transistor formed region 4. The contact hole 42 is formed down to the dummy gate interconnection 38a. The contact holes 42 are formed down to the source/drain regions 28S, 28D, 32S, 32D (see FIG. 11A to 11D).

Next, a barrier metal film (not illustrated) is formed on the entire surface by, e.g., sputtering. As the barrier metal film, Ti film and TiN film are sequentially formed.

Next, the conduction film of tungsten is formed on the entire surface by, e.g., CVD.

Then, the conduction film and the barrier metal film are polished by, e.g., CMP until the surface of the inter-layer insulation film 40 is exposed. Thus, in the contact holes 42 with the barrier metal film formed in, the conduction plugs 44a-44f of tungsten are respectively buried in. The conductor plug 44a is connected to the source region 28S of the PMOS transistor 34. The conductor plug 44b is connected to the drain region 28D of the PMOS transistor 34. The conductor plug 44c is connected to the source region 32S of the NMOS transistor 36. The conductor plug 44d is connected to the drain region 32D of the NMOS transistor 36. The conductor plug 44e is connected to the dummy gate interconnection 38a. The conductor plug 44f is connected to the gate interconnection 20 at the border between the PMOS transistor formed region 2 and the NMOS transistor formed region 4.

Next, the inter-layer insulation film 46 of, e.g. silicon oxide film is formed on the entire surface by, e.g., CVD.

As the inter-layer insulation film 46, a porous low-dielectric constant film or others for example, may be used.

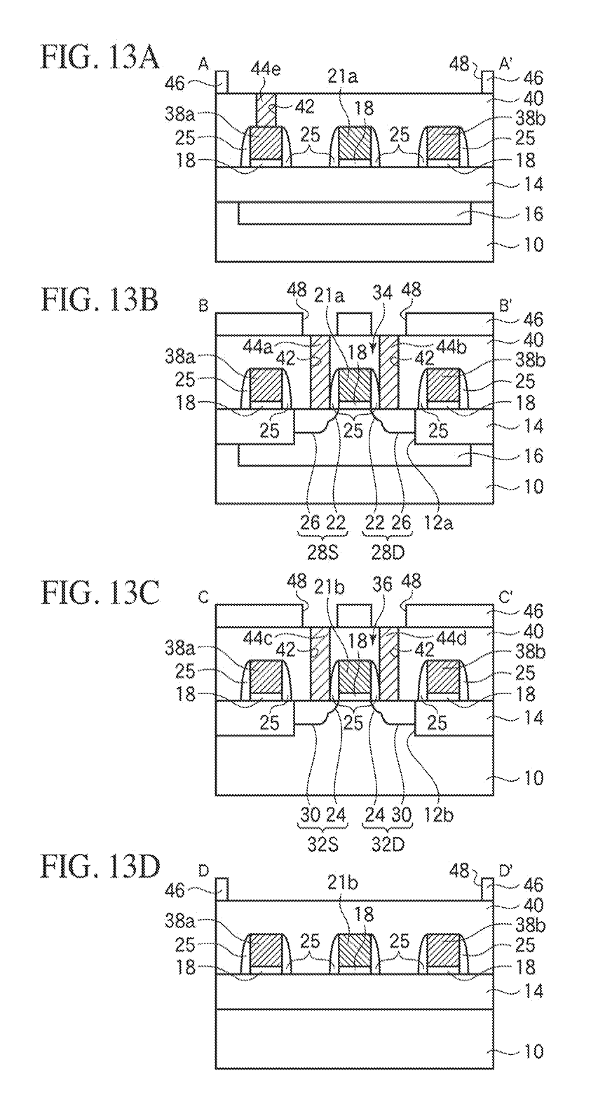

Then, by photolithography, the trenches 48 for the interconnections 50a-50c to be buried in are formed in a photoresist film. In the bottom surfaces of the trenches 48, the conductor plugs 44a-44f are respectively exposed (see FIG. 13A to 13D).

Next, the seed layer (not illustrated) of Cu is formed on the entire surface by, e.g., sputtering.

Next, the conduction film of Cu is formed on the entire surface by, e.g., electroplating.

Then, the conduction film, the seed layer and the barrier metal film are polished by, e.g., CMP until the surface of the inter-layer insulation film 46 is exposed. Thus, in the trenches 48 with the barrier metal film formed in, the interconnections 50a-50c formed of the conduction film, i.e., the power source line 50a, the ground line 50b and the signal line 50c are buried in.

The power source line 50a is electrically connected to the source region 28S of the PMOS transistor 34 via the conductor plug 44a. The power source line 50a is electrically connected to the dummy gate electrode 38a via the conductor plug 44e.

The ground line 50b is electrically connected to the source region 32S of the NMOS transistor 36 via the conductor plug 44c. A part of the ground line 50b is formed in parallel with the dummy gate interconnection 38a. Another part of the ground line 50b crosses the dummy gate interconnection 38a.

The signal line 50c is electrically connected to the drain region 28D of the PMOS transistor 34 via the conductor plug 44b and electrically connected to the drain region 32D of the NMOS transistor 36 via the conductor plug 44d. Thus, the drain region 28D of the PMOS transistor 34 and the drain region 32D of the NMOS transistor 36 are electrically connected.

The dummy gate interconnection 38b becomes electrically floating.

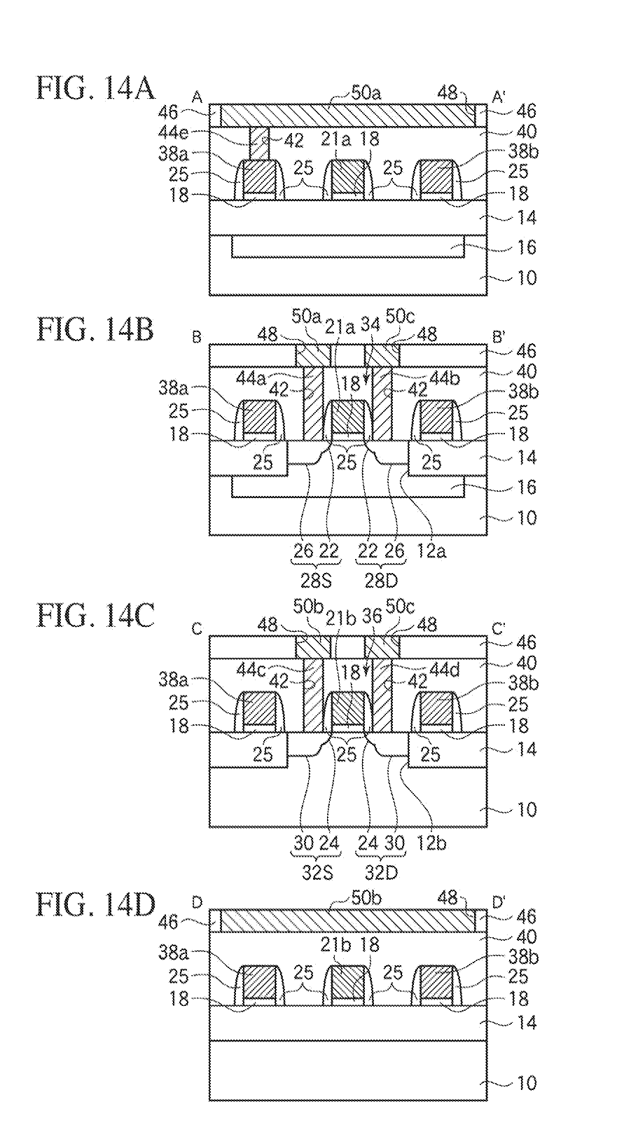

Thus, the semiconductor device according to the present embodiment is manufactured (see FIG. 14A to 14D).

### [b] Second Embodiment

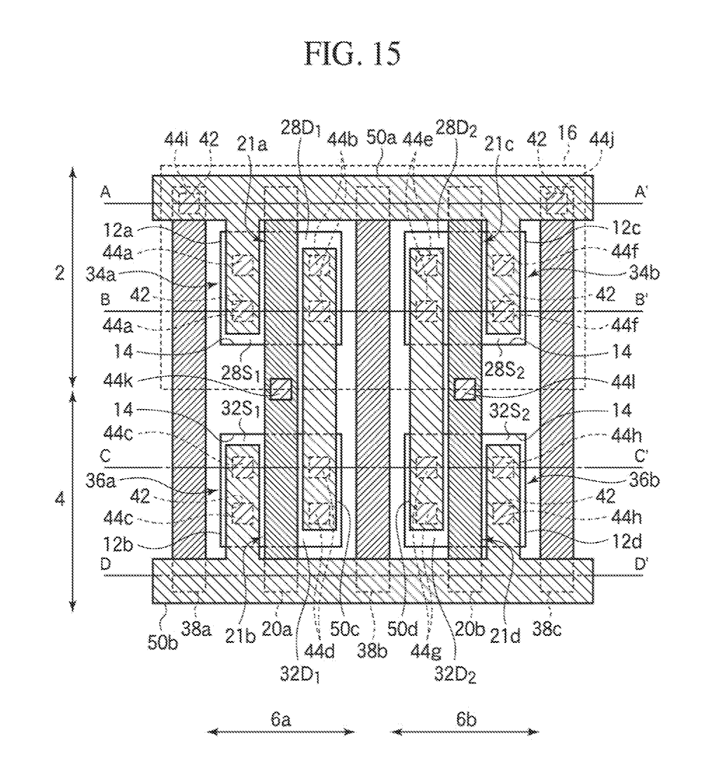

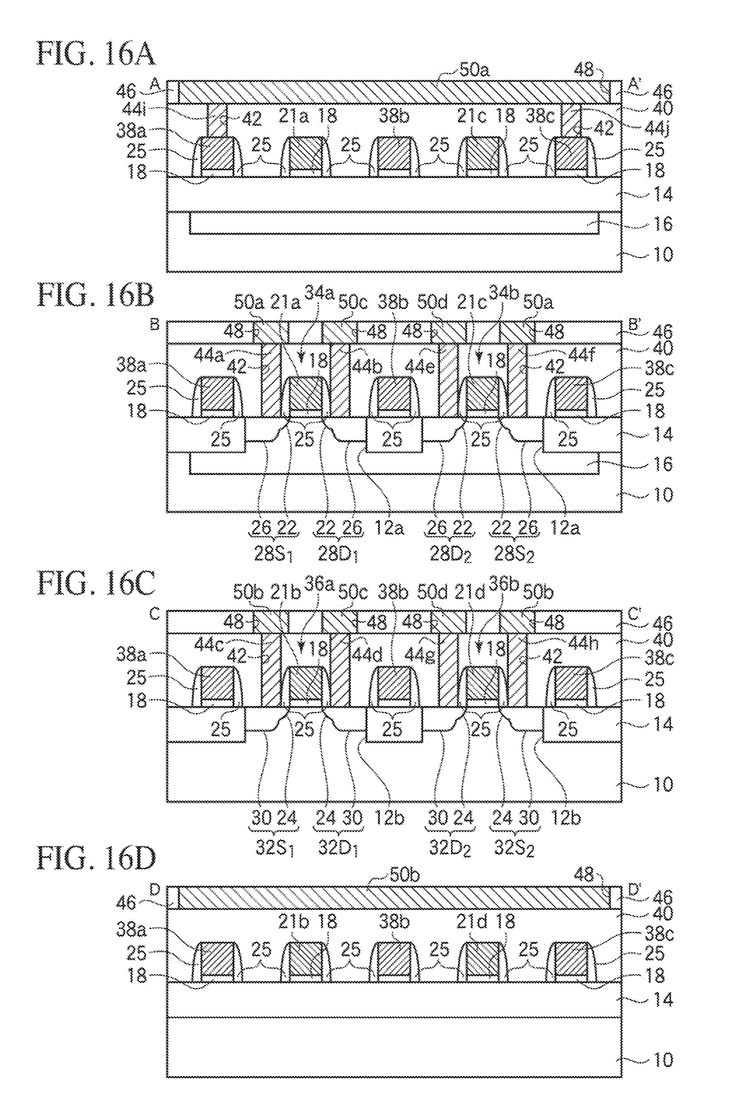

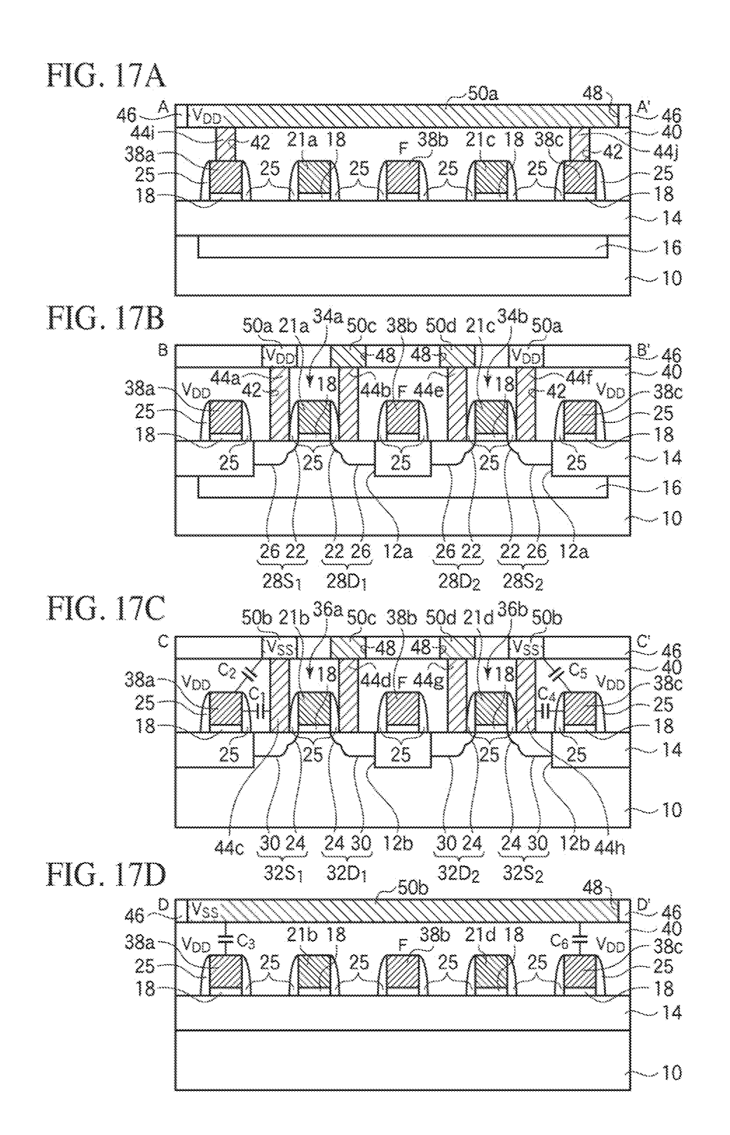

The semiconductor device according to a second embodiment will be described with reference to FIGS. 15 to 17D. FIG. 15 is a plan view of the semiconductor device according to the present embodiment. FIGS. 16A to 16D are sectional views of the semiconductor device according to the present embodiment (Part 1). FIGS. 17A to 17D are sectional views of the semiconductor device according to the present embodiment (Part 2). FIGS. 16A and 17A correspond to the A-A′ line section of FIG. 15. FIGS. 16B and 17B correspond to the B-B′ line section of FIG. 15. FIGS. 16C and 17C correspond to the C-C′ line section of FIG. 15. FIGS. 16D and 17D correspond to the D-D′ line section of FIG. 15. The same constituent members of the present embodiment as those of the semiconductor device according to the first embodiment and its manufacturing method illustrated in FIGS. 1 to 14D are represented by the same reference numbers not to repeat or to simplify the description.

The semiconductor device according to the present embodiment includes two unit cells 6a, 6b laid out adjacent to each other.

As illustrated in FIG. 15, device isolation regions 14 defining device regions 12a-12d are formed in a semiconductor substrate 10. The device regions 12a, 12c are formed in a PMOS transistor formed region 2. The device regions 12b, 12d are formed in a NMOS transistor formed region 4. The device region 12a is positioned on the left side of the drawing, and the device region 12c is positioned right of the device region 12a as viewed in the drawing. The device region 12b is positioned on the left side of the drawing, and the device region 12d is positioned right of the device region 12b as viewed in the drawing.

In the semiconductor substrate 10 in the PMOS transistor formed region 2, an N-type well 16 is formed.

On the semiconductor substrate 10 in the PMOS transistor formed region 2, a gate electrodes 21a, 21c are formed with gate insulation films 18 formed therebetween. On the semiconductor substrate 10 in the NMOS transistor formed region 4, gate electrodes 21b, 21d are formed with gate insulation films 18 formed therebetween.

The gate electrode 21a and the gate electrode 21b are parts of a gate interconnection 20a formed continuously in the PMOS transistor formed region 2 and the NMOS transistor formed region 4. The gate electrode 21c and the gate electrode 21d are parts of a gate interconnection 20b formed continuously in the PMOS transistor formed region 2 and the NMOS transistor formed region 4. As the gate interconnections 20a, 20b, polysilicon film or others, for example, is used.

In the gate interconnections 20a, 20b in the PMOS transistor formed region 2, a P-type dopant impurity is implanted, and thus the gate electrodes 21a, 21c of the PMOS transistors 34a, 34b are respectively formed. In the gate interconnection 20b in the NMOS transistor formed region 4, an N-type dopant impurity is implanted, and thus the gate electrodes 21b, 21d of the NMOS transistors 36a, 36b are respectively formed. The gate interconnection 20a crosses the device regions 12a, 12b. The gate interconnection 20b crosses the device regions 12c, 12d.

In the device regions 12a, 12c on both sides of the gate electrodes 21a, 21c of the PMOS transistor 34a, 34b, P-type lightly doped impurity regions 22 forming the shallow regions of the extension source/drain structure are formed.

In the device regions 12b, 12d on both sides of the gate electrodes 21b, 21d of the NMOS transistors 36a, 36b, N-type lightly doped impurity regions 24 forming the shallow regions of the extension source/drain structure are formed.

On the side walls of the gate interconnections 20, sidewall insulation films 25 are formed.

In the device regions 12a, 12c on both sides of the gate electrodes 21a, 21c of the PMOS transistors 34a, 34b with the sidewalls insulation films 25 formed on, heavily doped impurity regions 26 forming the deep regions of the extension source/drain structure are formed.

The lightly doped impurity region 22 and the heavily doped impurity region 26 form the source/drain regions 28S1, 28D1 of the PMOS transistor 34a. The lightly doped impurity region 22 and the heavily doped impurity region 26 form the source/drain regions 28S2, 28D2 of the PMOS transistor 34b. The source region 28S1 of the PMOS transistor 34a is formed in the device region 12a on the left side of the gate electrode 21a of the PMOS transistor 34a as viewed in the drawing. The drain region 28D1 of the PMOS transistor 34a is formed in the device region 12a on the right side of the gate electrode 21a of the PMOS transistor 34a as viewed in the drawing. The source region 28S2 of the PMOS transistor 34b is formed in the device region 12c on the right side of the gate electrode 21c of the PMOS transistor 34b as viewed in the drawing. The drain region 28D2 of the PMOS transistor 34b is formed in the device region 12c on the left side of the gate electrode 21c of the PMOS transistor 34b as viewed in the drawing.

In the device regions 12b, 12d on both sides of the gate electrodes 21b, 21d of the NMOS transistors 36a, 36b with the sidewall insulation films 25 formed on, heavily doped impurity regions 30 forming the deep region of the extension source/drain structure are formed.

The lightly doped impurity regions 24 and the heavily doped impurity regions 30 form the source/drain regions 32S1, 32D1 of the NMOS transistors 36a. The lightly doped impurity regions 24 and the heavily doped impurity regions 30 form the source/drain regions 32S2, 32D2 of the NMOS transistor 36b. The source region 32S1 of the NMOS transistor 36a is formed in the device region 12b of the gate electrode 21b of the NMOS transistor 36a as viewed in the drawing. The drain region 32D1 of the NMOS transistor 36a is formed in the device region 12b on the right side of the gate electrode 21b of the NMOS transistor 36a as viewed in the drawing. The source region 32S2 of the NMOS transistor 36b is formed in the device region 12d on the right side of the gate electrode 21d of the NMOS transistor 36b as viewed in the drawing. The drain region 32D2 of the NMOS transistor 36b is formed in the device region 12d on the left side of the gate electrode 21d of the NMOS transistor 36b as viewed in the drawing.

Thus, the PMOS transistor 34a including the gate electrode 21a and the source/drain regions 28S1, 28D1 is formed. The PMOS transistor 34b including the gate electrode 21c and the source/drain regions 28S2, 28D2 is formed. The NMOS transistor 36a including the gate electrode 21b and the source/drain regions 32S1, 32D1 is formed. The NMOS transistor 36b including the gate electrode 21d and the source/drain regions 32S2, 32D2 is formed.

On the device isolation region 14 on the left side of the gate interconnection 20a as viewed in the drawing, the dummy gate interconnection 38a is formed in parallel with the gate interconnection 20a. The dummy gate interconnection 38a is positioned left side of the device regions 12a, 12b as viewed in the drawing.

On the device isolation region 14 between the gate interconnection 20a and the gate interconnection 20b, the dummy gate interconnection 38b is formed in parallel with the gate interconnections 20a, 20b. The dummy gate interconnection 38b is positioned right of the device regions 12a, 12b as viewed in the drawing and positioned left of the device regions 12c, 12d as viewed in the drawing.

On the device isolation region 14 right of the gate interconnection 20c as viewed in the drawing, a dummy gate interconnection (a dummy gate electrode, a dummy gate pattern, a dummy pattern, a pattern) 38c is formed in parallel with the gate interconnection 20b. The dummy gate interconnection 38c is positioned right of the device regions 12c, 12d as viewed in the drawing.

The dummy gate interconnections 38a-38c are formed of, e.g., polysilicon film. In the dummy gate interconnections 38a-38c in the PMOS transistor formed region 2, a P-type dopant impurity, for example, is implanted. In the dummy gate electrodes 38a-38c in the NMOS transistor formed region 4, an N-type dopant impurity, for example, is implanted.

Also on the side walls of the dummy gate electrodes 38a-38c, the sidewall insulation films 25 are formed.

The inter-layer insulation film 40 is formed on the semiconductor substrate 10 with the PMOS transistors 34a, 34b, the NMOS transistors 36a, 36b and the dummy gate electrodes 38a-38c formed on.

In the inter-layer insulation film 40, the contact holes 42 are formed down to the source/drain regions 28S1, 28D1 of the PMOS transistor 34a. In the inter-layer insulation film 40, the contact holes 42 are formed down to the source/drain regions 28S2, 28D2 of the PMOS transistor 34b. In the inter-layer insulation film 40, the contact holes 42 are formed down to the source/drain regions 32S1, 32D1 of the NMOS transistor 36a. In the inter-layer insulation film 40, the contact holes 42 are formed down to the source/drain regions 32S2, 32D2 of the NMOS transistor 36b. In the inter-layer insulation film 40, the contact holes 42 are formed respectively down to the dummy interconnections 38a, 38c. In the inter-layer insulation film 40, the contact holes are formed respectively down to the gate interconnections 20a, 20b at the border between the PMOS transistor formed region 2 and the NMOS transistor formed region 4.

In the contact holes 42, the conductor plugs 44a-44l of, e.g., tungsten are buried. The conductor plug 44a is connected to the source region 28S1 of the PMOS transistor 34a. The conductor plug 44b is connected to the drain region 28D1 of the PMOS transistor 34a. The conductor plug 44c is connected to the source region 32S1 of the NMOS transistor 36a. The conductor plug 44d is connected to the drain region 32D1 of the NMOS transistor 36a. The conductor plug 44e is connected to the drain region 28D2 of the PMOS transistor 34b. The conductor plug 44f is connected to the source region 28D2 of the PMOS transistor 34b. The conductor plug 44g is connected to the drain region 32D2 of the NMOS transistor 36b. The conductor plug 44h is connected to the source region 32S2 of the NMOS transistor 36b. The conductor plug 44i is connected to the dummy gate interconnection 38a. The conductor plug 44j is connected to the dummy gate interconnection 38c. The conductor plugs 44k is connected to the gate interconnection 20a at the border between the PMOS transistor formed region 2 and the NMOS transistor formed region 4. The conductor plug 44l is connected to the gate interconnection 20b at the border between the PMOS transistor formed region 2 and the NMOS transistor formed region 4.

On the inter-layer insulation film 40 with the conductor plugs 44a-44l buried in, the inter-layer insulation film 46 is formed.

In the inter-layer insulation film 46, the trenches 48 for the interconnections 50a-50d buried in are formed.

In the trenches 48, the interconnections 50a-50d of, e.g., Cu, more specifically, the power source line 50a, the ground line 50b and the signal lines 50c, 50d are buried in.

The power source line 50a is electrically connected to the source region 28S1 of the PMOS transistor 34a via the conductor plug 44a. The power source line 50a is electrically connected to the source region 28S2 of the PMOS transistor 34b via the conductor plug 44f. The power source line 50a is electrically connected to the dummy gate electrode 38a via the conductor plug 44i. The power source line 50a is electrically connected to the dummy gate electrode 38c via the conductor plug 44j. The power source line 50a is to be connected to the power source potential VDD (see FIGS. 17A to 17D).

The ground line 50b is electrically connected to the source region 32S1 of the NMOS transistor 36a via the conductor plug 44c. The ground line 50b is electrically connected to the source region 32S2 of the NMOS transistor 36b via the conductor plug 44h. A part of the ground line 50b is formed in parallel with the respective dummy gate interconnections 38a, 38c. Another part of the ground line 50b crosses the respective dummy gate interconnections 38a, 38c. The ground line 50b is to be connected to the ground potential VSS (see FIGS. 17A to 17D).

The signal line 50c is electrically connected to the drain region 28D1 of the PMOS transistor 34a via the conductor plug 44b while electrically connected to the drain region 32D1 of the NMOS transistor 36a via the conductor plug 44d.

The signal line 50d is electrically connected to the drain region 28D2 of the PMOS transistor 34b via the conductor plug 44e while electrically connected to the drain region 32D2 of the NMOS transistor 36b via the conductor plug 44g.

The dummy gate interconnection 38b formed on the device isolation region 14 between the gate interconnection 20a and the gate interconnection 20b is electrically floating.

In the present embodiment, the dummy gate interconnection 38b is electrically floating for the following reason.

That is, the conductor plugs 44b, 44d, 44e, 44g connected to the drain regions 28D1, 32D1, 28D2, 32D2 are connected to the signal lines 50c, 50d. In the case that the dummy gate interconnection 38b adjacent to the conductor plugs 44b, 44d, 44e, 44g is connected to the power source potential VDD and the ground potential VSS, the conductor plugs 44b, 44d, 44e, 44g capacitively coupled with the dummy gate electrode 38b, which causes signal delay. Then, in the present embodiment, to prevent such signal delay, the dummy gate interconnection 38b adjacent to the conductor plugs 44b, 44d, 44e, 44g connected to the drain regions 28D1, 32D1, 28D2, 32D2 is electrically floating.

Thus, the semiconductor device according to the present embodiment is formed.

According to the present embodiment, the dummy gate interconnection 38a is connected to the power source potential VDD while the conductor plug 44c connected to the source region 32S1 of the NMOS transistor 36a is connected to the ground potential VSS. Thus, according to the present embodiment, a decoupling capacitance C1 can be obtained between the dummy gate interconnection 38a and the conductor plug 44c (see FIGS. 17A to 17D).

In the present embodiment, the dummy gate interconnection 38a is connected to the power source potential VDD while a part of the ground line 50b is formed in parallel with the dummy gate interconnection 38a. Thus, a decoupling capacitance C2 can be obtained between the dummy gate interconnection 38a and the ground line 50b (see FIGS. 17A to 17D).

According to the present embodiment, the dummy gate interconnection 38a is connected to the power source potential VDD while another part of the ground line 50b crosses the dummy gate interconnection 38a. Thus, a decoupling capacitance C3 can be obtained between the dummy gate electrode 38a and the ground line 50b (see FIGS. 17A to 17D).

According to the present embodiment, the dummy gate interconnection 38c is connected to the power source potential VDD while the conductor plug 44h connected to the source region 32S2 of the NMOS transistor 36b is connected to the ground potential VSS. Thus, according to the present embodiment, a decoupling capacitance C4 can be obtained between the dummy gate interconnection 38c and the conductor plug 44h (see FIGS. 17A to 17D).

In the present embodiment, the dummy gate interconnection 38c is connected to the power source potential VDD while a part of the ground line 50b is formed in parallel with the dummy gate interconnection 38c. Thus, a decoupling capacitance C5 can be obtained between the dummy gate interconnection 38c and the ground line 50b (see FIGS. 17A to 17D).

According to the present embodiment, the dummy gate interconnection 38c is connected to the power source potential VDD while another part of the ground line 50b crosses the dummy gate interconnection 38c. Thus, a decoupling capacitance C6 can be obtained between the dummy gate electrode 38c and the ground line 50b (see FIGS. 17A to 17D).

In the present embodiment as well, such decoupling capacitances are formed in the respective unit cells 6a, 6b, which makes it unnecessary to provide decoupling capacitors of a large opposed area separate from the unit cells 6a, 6b. When such decoupling capacitors are provided separate from the unit cells 6a, 6b, the area necessary to form such decoupling capacitors can be small. In the present embodiment as well, the semiconductor device can be downsized.

In the present embodiment as well, the dummy gate interconnection 38b positioned on the side of the drain regions 28D1, 28D2, 32D1, 32D2 of the transistors 34a, 34b, 36a, 36b is electrically floating. Accordingly, the capacitive coupling of the conductor plugs 44b, 44d, 44e, 44g connected to the drain regions 28D1, 28D2, 32D1, 32D2 with the dummy gate interconnection 38b can be prevented. In the present embodiment as well, signal delay in the signal lines 50c, 50d electrically connected to the drain regions 28D1, 28D2, 32D1, 32D2 can be prevented.

### [c] Third Embodiment

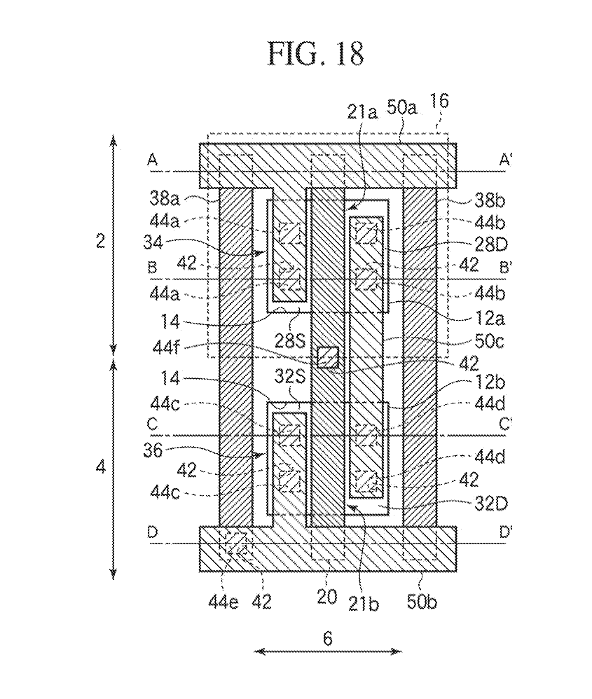

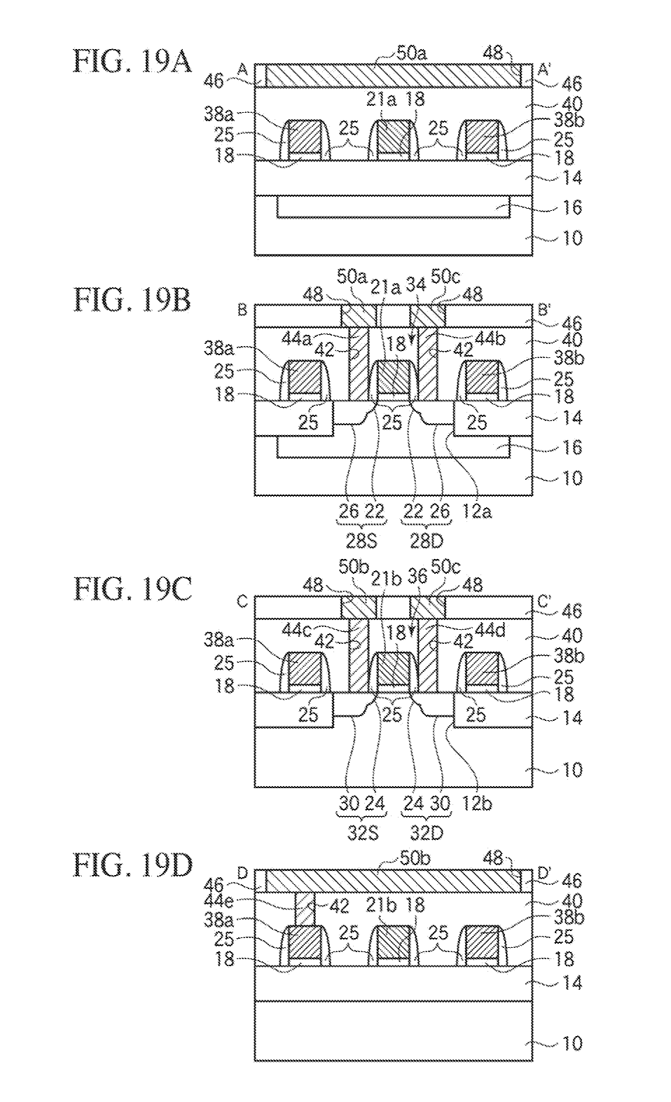

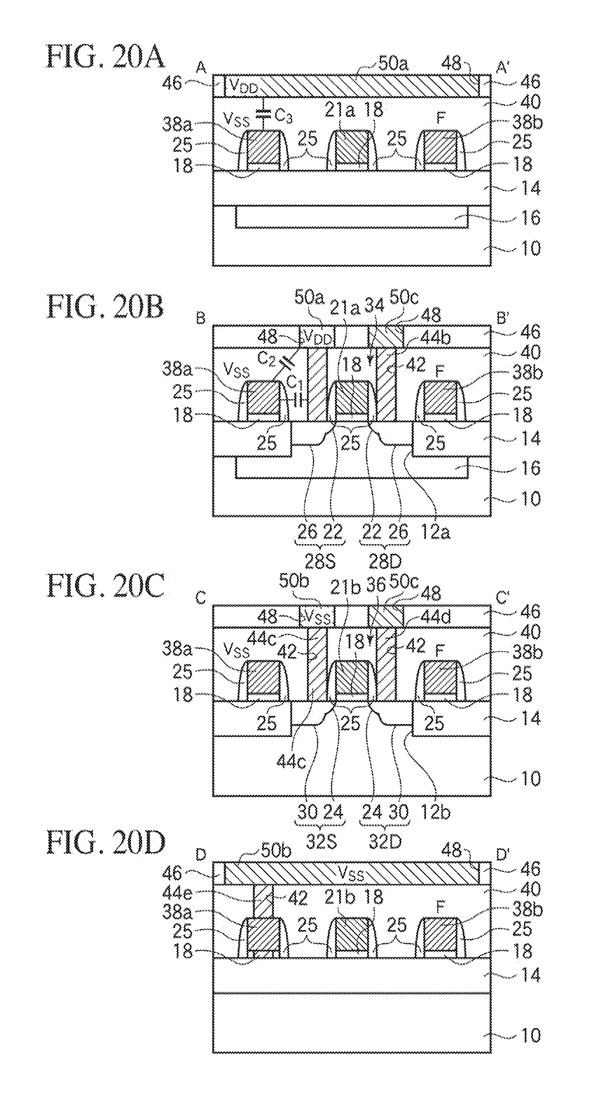

The semiconductor device according to a third embodiment will be described with reference to FIGS. 18 to 20D. FIG. 18 is a plan view of the semiconductor device according to the present embodiment. FIGS. 19A to 19D are sectional views of the semiconductor device according to the present embodiment (Part 1). FIGS. 20A to 20D are sectional views of the semiconductor device according to the present embodiment (Part 2). FIGS. 19A and 20A correspond to the A-A′ line section of FIG. 18. FIGS. 19B and 20B correspond to the B-B′ line section of FIG. 18. FIGS. 19C and 20C correspond to the C-C′ line section of FIG. 18. FIGS. 19D and 20D correspond to the D-D′ line section of FIG. 18. The same members of the present embodiment as those of the semiconductor device according to the first or the second embodiment and its manufacturing method are represented by the same reference numbers not to repeat or to simplify the description.

The present embodiment according to the present embodiment has the dummy gate interconnection 38a connected to the ground potential VSS.

As illustrated in FIG. 18, in the device region 12a on the left side of the gate electrode 21a of the PMOS transistor 34 as viewed in the drawing, the source region 28S of the extension source/drain structure is formed. In the device region 12a on the right side of the gate electrode 21a of the PMOS transistor 34, the source region 28D of the extension source/drain structure is formed.

In the device region 12b on the left side of the gate electrode 21b of the NMOS transistor 34 as viewed in the drawing, the source region 32S of the extension source/drain structure is formed. In the device region 12b on the right side of the gate electrode 21b of the NMOS transistor 34 as viewed in the drawing, the source region 32D of the extension source/drain structure is formed.

On the device isolation region 14 on the left side of the gate interconnection 20 as viewed in the drawing, the dummy gate interconnection 38a is formed in parallel with the gate interconnection 20. The dummy gate interconnection 38a is positioned left of the device regions 12a, 12b as viewed in the drawing.

On the device isolation region 14 on the right side of the gate interconnection 20 as viewed in the drawing, the dummy gate interconnection 38b is formed in parallel with the gate interconnection 20. The dummy gate interconnection 38b is positioned right of the device regions 12a, 12b as viewed in the drawing.

In the inter-layer insulation film 40, the contact holes 42 down to the source/drain regions 28S, 28D of the PMOS transistor 34 and the contact holes 42 down to the source/drain regions 32S, 32D of the NMOS transistor 36 are respectively formed. In the inter-layer insulation film 40, the contact hole 42 down to the dummy gate interconnection 38a is formed. In the inter-layer insulation film 40, the contact hole 42 down to the gate interconnection 20 at the border between the PMOS transistor formed region 2 and the NMOS transistor formed region 4 is formed.

In the contact holes 42, the conductor plugs 44a-44f of, e.g., tungsten are buried. The conductor plug 44a is connected to the source region 28S of the PMOS transistor 34. The conductor plug 44b is connected to the drain region 28D of the PMOS transistor 34. The conductor plug 44c is connected to the source region 32S of the NMOS transistor 36. The conductor plug 44d is connected to the drain region 32D of the NMOS transistor 36. The conductor plug 44e is connected to the dummy gate interconnection 38a. The conductor plug 44f is connected to the gate interconnection 20.

In the inter-layer insulation film 46, the trenches 48 for the lines to be buried in are formed.

In the trenches 48, the lines 50a-50c of, e.g., Cu, more specifically, the power source line 50a, the ground line 50b and the signal line 50c are buried.

The power source line 50a is electrically connected to the source region 28S of the PMOS transistor 34 via the conductor plug 44a. The power source line 50a is electrically connected to, e.g., the power source potential VDD (see FIGS. 20A to 20D). A part of the power source line 50a is formed in parallel with the dummy gate interconnection 38a. Another part of the power source line 50a crosses the dummy gate interconnection 38a.

The ground line 50b is electrically connected to the source region 32S of the NMOS transistor 36 via the conductor plug 44c. The ground line 50b is electrically connected to the dummy gate electrode 38a via the conductor plug 44e. The ground line 50b is to be connected to, e.g., the ground potential VSS (see FIGS. 20A to 20D).

The signal line 50c is electrically connected to the drain region 28D of the PMOS transistor 34 via the conductor plug 44b while electrically connected to the drain region 32D of the NMOS transistor 36 via the conductor plug 44d.

The dummy gate interconnection 38b formed on the device isolation region 14 on the right side of the gate interconnection 20 as viewed in the drawing is electrically floating.

Thus, the semiconductor device according to the present embodiment is formed.

According to the present embodiment, the dummy gate interconnection 38a is connected to the ground potential VSS, and the conductor plug 44a connected to the source region 28S of the PMOS transistor 34 is connected to the power source potential VDD. Thus, according to the present embodiment, a decoupling capacitance C1 can be obtained between the dummy gate interconnection 38a and the conductor plug 44a (see FIGS. 20A to 20D).

According to the present embodiment, the dummy gate electrode 38a is connected to the ground potential VSS, and a part of the power source line 50a is formed in parallel with the dummy gate interconnection 38a, whereby a decoupling capacitance C2 can be obtained between the dummy gate interconnection 38a and the power source line 50a (see FIGS. 20A to 20D).

According to the present embodiment, the dummy gate interconnection 38a is connected to the ground potential VSS, and another part of the power source line 50a crosses the dummy gate interconnection 38a, whereby a decoupling capacitance C3 can be obtained between the dummy gate electrode 38a and the power source line 50a (see FIGS. 20A to 20D).

As described above, the dummy gate interconnection 38a maybe connected to the ground potential VSS. In the present embodiment as well, such decoupling capacitances are formed in the unit cell 6, which makes it unnecessary to provide a decoupling capacitor of a large opposed area separate from the unit cell 6. Even when a decoupling capacitor is provided separate from the unit cell 6, the area necessary to form such decoupling capacitor can be small. Thus, according to the present embodiment as well, the semiconductor device can be downsized.

In the present embodiment as well, the dummy gate interconnection 38b positioned on the side of the drain region 28D of the transistor 34 is electrically floating. Thus, the conductor plug 44b connected to the drain region 28D can be prevented from the capacitive coupling with the dummy gate interconnection 38b. Thus, according to the present embodiment as well, signal delay in the signal line 50c electrically connected to the drain region 28D can be prevented.

### [d] Fourth Embodiment

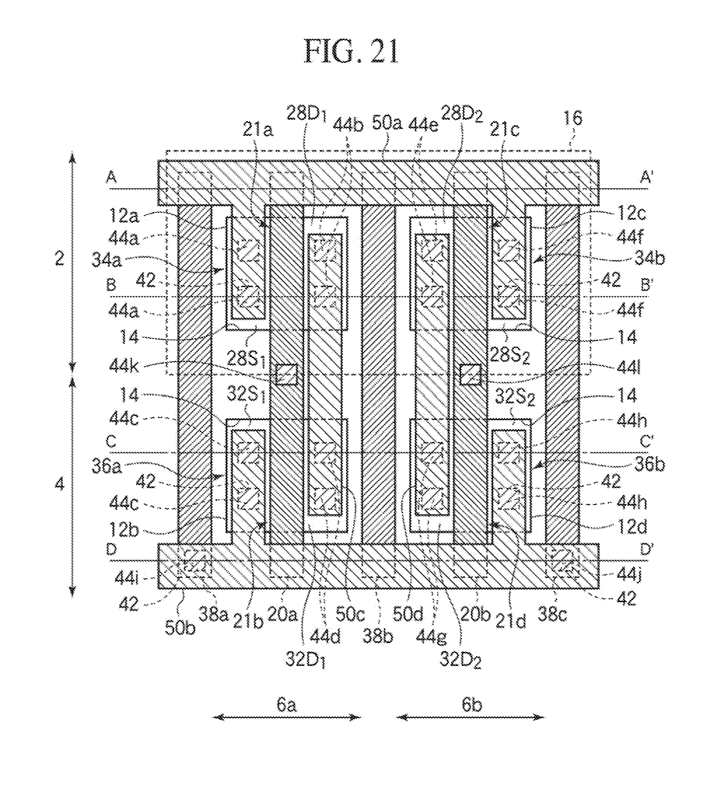

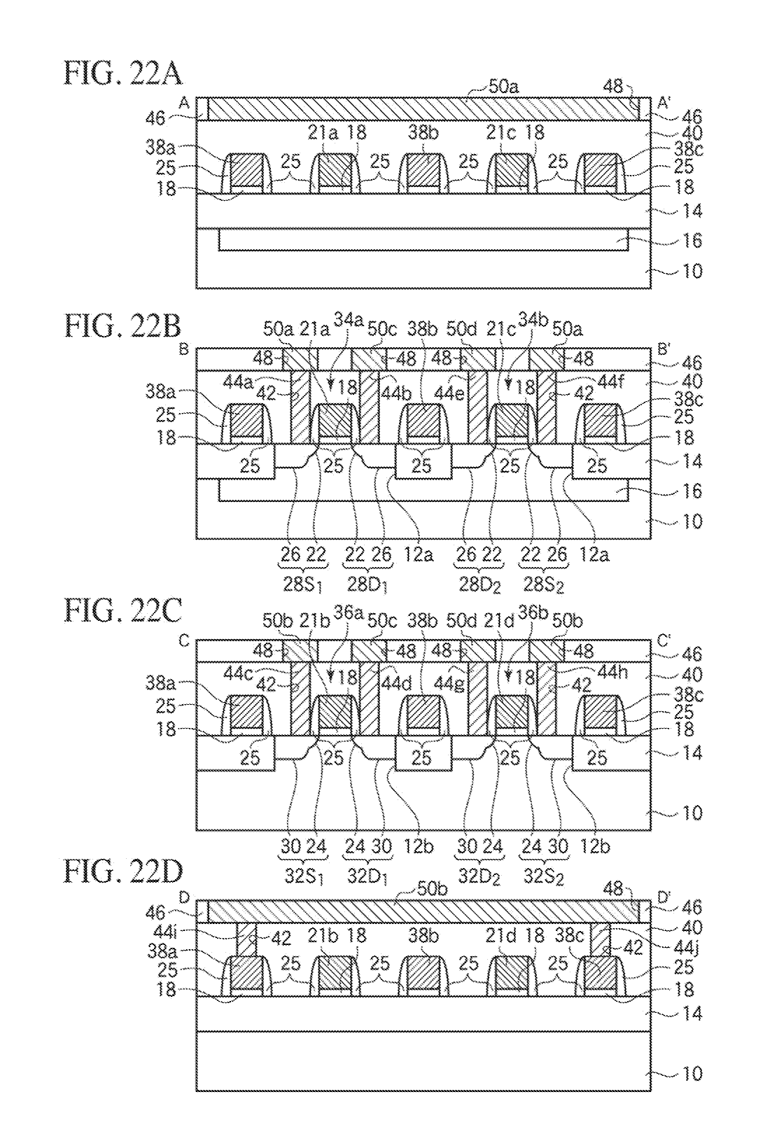

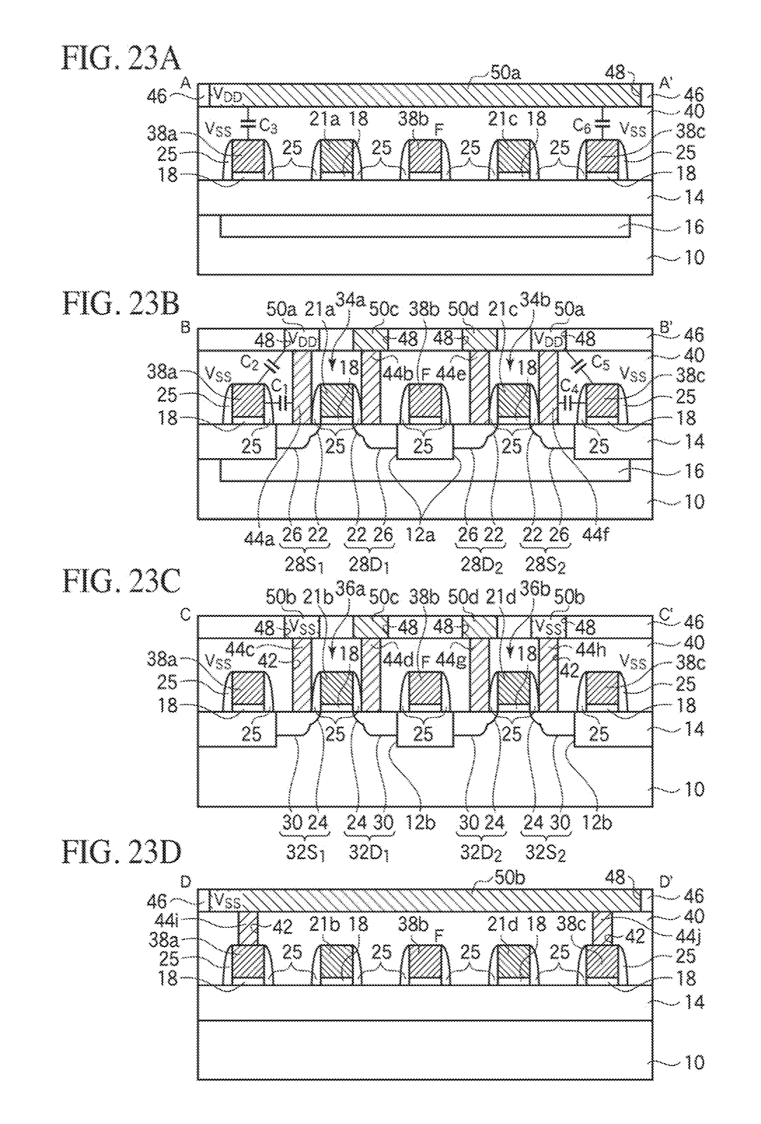

The semiconductor device according to a fourth embodiment will be described with reference to FIGS. 21 to 23D. FIG. 21 is a plan view of the semiconductor device according to the present embodiment. FIGS. 22A to 22D are sectional views of the semiconductor device according to the present embodiment (Part 1). FIGS. 23A to 23D are sectional views of the semiconductor device according to the present embodiment (Part 2). FIGS. 22A and 23A correspond to the A-A′ line section of FIG. 21. FIGS. 22B and 23B correspond to the B-B′ line section of FIG. 21. FIGS. 22C and 23C correspond to the C-C′ line of FIG. 21. FIGS. 22D and 23D correspond to the D-D′ line of FIG. 21. The same members of the present embodiment as those of the semiconductor device according to the first to the third embodiment and its manufacturing method illustrated in FIGS. 1 to 20D are represented by the same reference numbers not to repeat or to simplify the description.

The semiconductor device according to the present embodiment has 2 unit cells 6a, 6b laid out adjacent to each other and has the dummy gate interconnections 38a, 38c to be connected to the ground potential VSS.

As illustrated in FIG. 21, in the device region 12a left of the gate electrode 21a of the PMOS transistor 34a as viewed in the drawing, the source region 28S1 of the extension source/drain structure is formed. In the device region 12a right of the gate electrode 21a of the PMOS transistor 34a as viewed in the drawing, the drain region 28D1 of the extension source/drain structure is formed.

In the device region 12b left of the gate electrode 21b of the NMOS transistor 36a as viewed in the drawing, the source/drain region 32S1 of the extension source/drain structure is formed. In the device region 12b right of the gate electrode 21b of the NMOS transistor 36a, the drain region 32D1 of the extension source/drain structure is formed.

In the device region 12c right of the gate electrode 21c of the PMOS transistor 34b as viewed in the drawing, the drain region 28D2 of the extension source/drain structure is formed. In the device region 12c right of the gate electrode 21c of the PMOS transistor 34b as viewed in the drawing, the source region 28S2 of the extension source/drain structure is formed.

In the device region 12d left of the gate electrode 21d of the NMOS transistor 36b as viewed in the drawing, the drain region 32D2 of the extension source/drain structure is formed. In the device region 12d right of the gate electrode 21b of the NMOS transistor 36b, the source region 32S2 of the extension source/drain structure is formed.

On the device isolation region 14 left of the device regions 12a, 12b as viewed in the drawing, the dummy gate interconnection 38a is formed in parallel with the gate interconnection 20. On the device isolation region 14 right of the device regions 12c, 12d as viewed in the drawing, the dummy gate electrode 38c is formed in parallel with the gate interconnection 20b. On the device isolation region 14 between the gate interconnection 20a and the gate interconnection 20b, a dummy interconnection 38b is formed in parallel with the gate interconnections 20a, 20b.

In the inter-layer insulation film 40, the conductor plug 44a connected to the source region 28S1 of the PMOS transistor 34a is buried. In the inter-layer insulation film 40, the conductor plug 44b connected to the drain region 28D1 of the PMOS transistor 34a is buried. In the inter-layer insulation film 40, the conductor plug 44c connected to the source region 32S1 of the NMOS transistor 36a is buried. In the inter-layer insulation film 40, the conductor plug 44d connected to the source region 32D1 of the NMOS transistor 36a is buried.

In the inter-layer insulation film 40, the conductor plug 44e connected to the drain region 28D2 of the PMOS transistor 34b is buried. In the inter-layer insulation film 40, the conductor plug 44f connected to the source region 28S2 of the PMOS transistor 34b is buried. In the inter-layer insulation film 40, the conductor plug 44g connected to the drain region 32D2 of the NMOS transistor 36b is buried. In the inter-layer insulation film 40, the conductor plug 44h connected to the source region 32S2 of the NMOS transistor 36b is buried.

In the inter-layer insulation film 40, the conductor plug 44i connected to the dummy gate electrode 38a is buried. In the inter-layer insulation film 40, the conductor plug 44j connected to the dummy gate electrode 38c is buried. In the inter-layer insulation film 40, the conductor plug 44k connected to the gate interconnection 20a near the border between the PMOS transistor formed region 2 and the NMOS transistor formed region 4 is buried. In the inter-layer insulation film 40, the conductor plug 44l connected to the gate interconnection 20b near the border between the PMOS transistor formed region 2 and the NMOS transistor formed region 4 is buried.

The power source line 50a is electrically connected to the source region 28S1 of the PMOS transistor 34a via the conductor plug 44a. The power source line 50a is electrically connected to the source region 28S2 of the PMOS transistor 34b via the conductor plug 44f. The power source line 50a is to be connected to the power source potential VDD (see FIGS. 23A to 23D).

The ground line 50b is electrically connected to the source region 32S1 of the NMOS transistor 36a via the conductor plug 44c. The ground line 50b is electrically connected to the source region 32S2 of the NMOS transistor 36b via the conductor plug 44h. The ground line 50b is electrically connected to the dummy gate electrode 38a via the conductor plug 44i. The ground line 50b is electrically connected to the dummy gate electrode 38c via the conductor plug 44j. A part of the ground line 50b is formed in parallel with the respective dummy gate interconnections 38a, 38c. Another part of the power source line 50a crosses the respective dummy gate interconnections 38a 38c. The ground line 50b is to be connected to the ground potential VSS (see FIGS. 23A to 23D).

The signal line 50c is electrically connected to the drain region 28D1 of the PMOS transistor 34a via the conductor plug 44b while connected to the drain region 32D1 of the NMOS transistor 36a via the conductor plug 44d.

The signal line 50d is electrically connected to the drain region 28D2 of the PMOS transistor 34b via the conductor plug 44e while electrically connected to the drain region 32D2 of the NMOS transistor 36b via the conductor plug 44g.

The dummy gate interconnection 38b formed on the device isolation region 14 between the gate interconnection 20a and the gate interconnection 20b is electrically floating.

Thus, the semiconductor device according to the present embodiment is formed.

In the present embodiment, the dummy gate interconnection 38a is connected to the ground potential VSS, and the conductor plug 44a connected to the source region 28S1 of the PMOS transistor 36a is connected to the power source potential VDD. Thus, according to the present embodiment, a decoupling capacitance C1 can be obtained between the dummy gate interconnection 38a and the conductor plug 44a (see FIGS. 23A to 23D).

In the present embodiment, the dummy gate interconnection 38a is connected to the ground potential VSS, and the a part of the power source line 50a is formed in parallel with the dummy gate interconnection 38a. Thus, a decoupling capacitance C2 can be obtained between the dummy gate interconnection 38a and the power source line 50a (see FIGS. 23A to 23D).

In the present embodiment, the dummy gate interconnection 38a is connected to the ground potential VSS, and another part of the power source line 50a crosses the dummy gate interconnection 38a. Thus, a decoupling capacitance C3 can be obtained between the dummy gate interconnection 38a and the power source line 50a (see FIGS. 23A to 23D).

In the present embodiment, the dummy gate interconnection 38c is connected to the ground potential VSS, and the conductor plug 44f connected to the source region 28D2 of the PMOS transistor 34b is connected to the power source potential VDD. Thus, a decoupling capacitance C4 can be obtained between the dummy gate interconnection 38c and the conductor plug 44f (see FIGS. 23A to 23D).

In the present embodiment, the dummy gate interconnection 38c is connected to the ground potential VSS, and the a part of the power source line 50a is formed in parallel with the dummy gate interconnection 38c. Thus, a decoupling capacitance C5 can be obtained between the dummy gate interconnection 38c and the power source line 50a (see FIG. 23A to 23D).

In the present embodiment, the dummy gate interconnection 38c is connected to the ground potential VSS, and another part of the power source line 50a crosses the dummy gate interconnection 38c. Thus, a decoupling capacitance C6 can be obtained between the dummy gate electrode 38c and the power source line 50a (see FIGS. 23A to 23D).

As described above, in the present embodiment as well, decoupling capacitances are formed in the unit cells 6a, 6b, which makes it unnecessary to provide a large decoupling capacitor of a large opposed area separate from the unit cells 6a, 6b. Even when a decoupling capacitor is provided separate from the unit cells 6a, 6b, the area necessary to form such decoupling capacitors can be small. Thus, according to the present embodiment as well, the semiconductor device can be downsized.

In the present embodiment as well, the dummy gate interconnection 38b positioned on the side of the drain regions 28D1, 28D2, 32D1, 32D2 of the transistors 34a, 34b, 36a, 36b is electrically floating. Thus, the capacitive coupling of the conductor plugs 44b, 44d, 44e, 44g connected to the drain regions 28D1, 28D2, 32D1, 32D2 with the dummy gate interconnection 38b can be prevented. Thus, in the present embodiment as well, signal delay in the signal lines 50c, 50d electrically connected to the drain regions 28D1, 28D2, 32D1, 32D2 can be prevented.

### [e] Fifth Embodiment

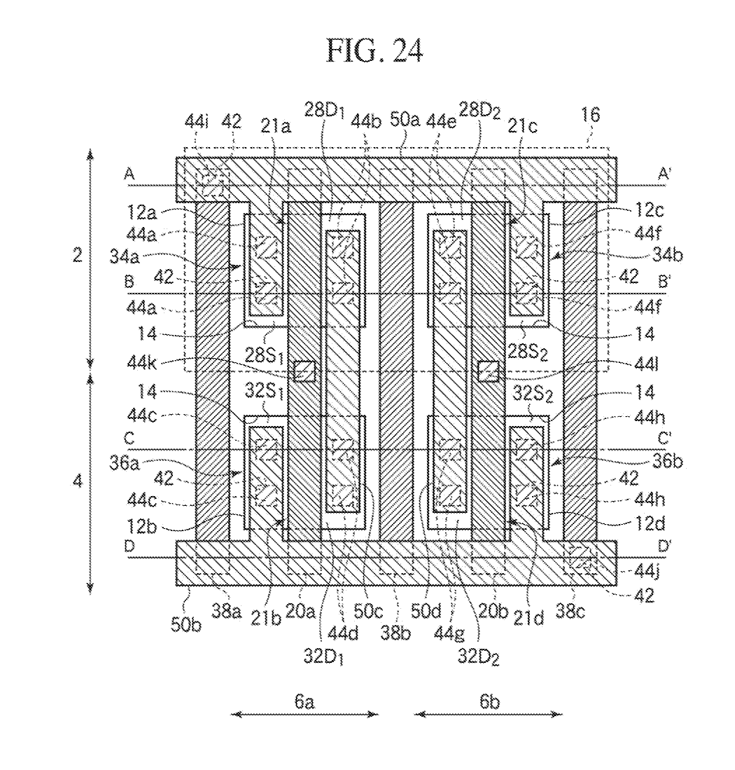

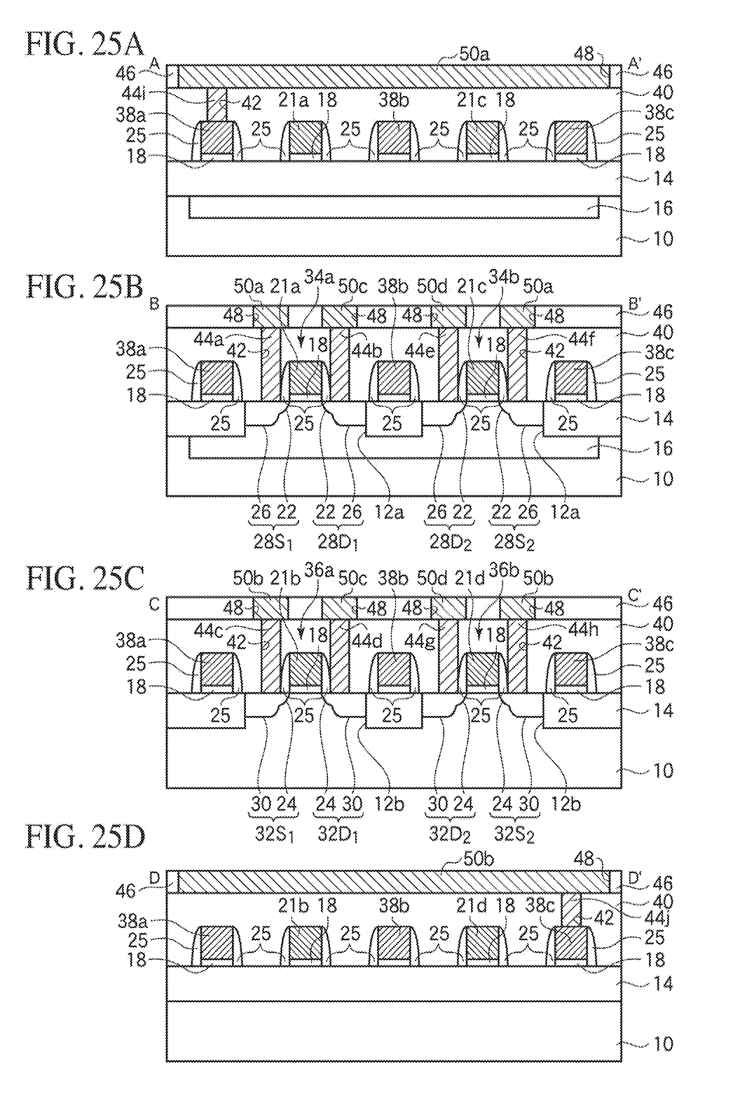

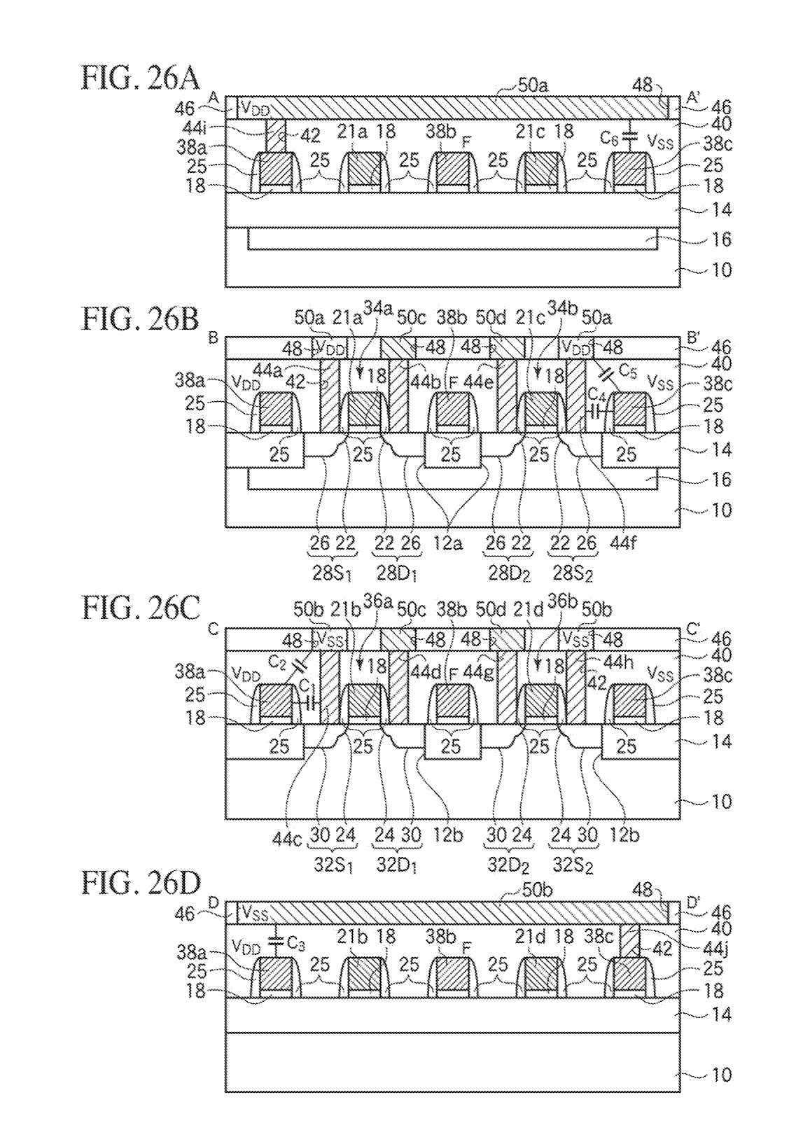

The semiconductor device according to a fifth embodiment will be described with reference to FIGS. 24 to 26D. FIG. 24 is a plan view of the semiconductor device according to the present embodiment. FIGS. 25A to 25D are sectional views of the semiconductor device according to the present embodiment (Part 1). FIGS. 26A to 26D are sectional views of the semiconductor device according to the present embodiment (Part 2). FIGS. 25A and 26A correspond to the A-A′ line section of FIG. 24. FIGS. 25B and 26B correspond to the B-B′ line section of FIG. 24. FIGS. 25C and 26C correspond to the C-C′ line section of FIG. 24. FIGS. 25D and 26D correspond to the D-D′ line of FIG. 24. The same members of the present embodiment as those of the semiconductor device according to the first to the fourth embodiment and its manufacturing method illustrated in FIGS. 1 to 23D are represented by the same reference numbers not to repeat or to simplify the description.

The semiconductor device according to the present embodiment has two unit cells 6a, 6b laid out adjacent to each other and has the dummy gate interconnection 38a connected to the power source potential VDD and the dummy gate electrode 38b connected to the ground potential VSS.

As illustrated in FIG. 24, in the device region 12a left of the gate electrode 21a of the PMOS transistor 34a as viewed in the drawing, the source region 28S1 of the extension source/drain structure is formed. In the device region 12a right of the gate electrode 21a of the PMOS transistor 34a as viewed in the drawing, the drain region 28D1 of the extension source/drain structure is formed.

In the device region 12b right of the gate electrode 21b of the NMOS transistor 36a as viewed in the drawing, the source region 32S1 of the extension source drain structure is formed. In the device region 12b right of the gate electrode 21b of the NMOS transistor 36a as viewed in the drawing, the drain region 32D1 of the extension source/drain structure is formed.

In the device region 12c left of the gate electrode 21c of the PMOS transistor 34b as viewed in the drawing, the drain region 28D2 of the extension source/drain structure is formed. In the device region 12c right of the gate electrode 21c of the PMOS transistor 34b as viewed in the drawing, the source region 28S2 of the extension source/drain structure is formed.

In the device region 12d left of the gate electrode 21d of the NMOS transistor 36b as viewed in the drawing, the drain region 32D2 of the extension source/drain structure is formed. In the device region 12d right of the gate electrode 21b of the NMOS transistor 36b as viewed in the drawing, the source region 32S2 of the extension source drain structure is formed.

On the device isolation region 14 left of the device regions 12a, 12b as viewed in the drawing, the dummy gate interconnection 38a is formed in parallel with the gate interconnection 20a. On the device isolation region 14 right of the device regions 12c, 12d as viewed in the drawing, the dummy electrode 38c is formed in parallel with the gate interconnection 20b. On the device isolation region 14 between the gate interconnection 20a and the gate interconnection 20b, the dummy gate interconnection 38b is formed in parallel with the gate interconnections 20a, 20b.

In the inter-layer insulation film 40, the conductor plug 44a connected to the source region 28S1 of the PMOS transistor 34a is buried. In the inter-layer insulation film 40, the conductor plug 44d connected to the drain region 28D1 of the PMOS transistor 34a is buried.

In the inter-layer insulation film 40, the conductor plug 44c connected to the source region 32S1 of the NMOS transistor 36a is buried. In the inter-layer insulation film 40, the conductor plug 44d connected to the drain region 32D1 of the NMOS transistor 36a is buried.

In the inter-layer insulation film 40, the conductor plug 44e connected to the drain region 28D2 of the PMSO transistor 34b is buried. In the inter-layer insulation film 40, the conductor plug 44f connected to the source region 28S2 of the PMOS transistor 34b is buried.

In the inter-layer insulation film 40, the conductor plug 44g connected to the drain region 32D2 of the NMOS transistor 36b is buried. In the inter-layer insulation film 40, the conductor plug 44h connected to the source region 32S2 of the NMOS transistor 36b is buried.

In the inter-layer insulation film 40, the conductor plug 44i connected to the dummy gate electrode 38a is buried. In the inter-layer insulation film 40, the conductor plug 44j connected to the dummy gate electrode 38c is buried.

In the inter-layer insulation film 40, the conductor plug 44k connected to the gate interconnection 20a near the border between the PMOS transistor formed region 2 and the NMOS transistor formed region 4 is buried. In the inter-layer insulation film 40, the conductor plug 44l connected to the gate interconnection 20b near the border between the PMOS transistor formed region 2 and the NMOS transistor formed region 4.

The power source line 50a is electrically connected to the source region 28S1 of the PMOS transistor 34a via the conductor plug 44a. The power source line 50a is electrically connected to the source region 28S2 of the PMOS transistor 34b via the conductor plug 44f. The power source line 50a is electrically connected to the dummy gate electrode 38a via the conductor plug 44i. A part of the power source line 50a is formed in parallel with the dummy gate interconnections 38a, 38c. Another part of the power source line 50a crosses the dummy gate interconnections 38a, 38c. The power source line 50a is to be connected to the power source potential VDD (see FIGS. 26A to 26D).

The ground line 50b is electrically connected to the source region 32S1 of the NMOS transistor 36a via the conductor plug 44c. The ground line 50b is electrically connected to the source region 32S2 of the NMOS transistor 36b via the conductor plug 44h. The ground line 50b is electrically connected to the dummy gate interconnection 38c via the conductor plug 44j. A part of the ground line 50b is formed in parallel with the dummy gate interconnections 38a, 38c. Another part of the ground line 50b crosses the dummy gate interconnections 38a, 38c. The ground line 50b is to be connected to the ground potential VSS (see FIGS. 26A to 26D).

The signal line 50c is electrically connected to the drain region 28D1 of the PMOS transistor 34a via the conductor plug 44b and electrically connected to the drain region 32D1 of the NMOS transistor 36a via the conductor plug 44d.

The signal line 50d is electrically connected to the drain region 28D2 of the PMOS transistor 34b via the conductor plug 44e and electrically connected to the drain region 32D2 of the NMOS transistor 36b via the conductor plug 44g.

The dummy gate interconnection 38b formed on the device isolation region 14 between the gate interconnection 20a and the gate interconnection 20b is electrically floating.

Thus, the semiconductor device according to the present embodiment is formed.

In the present embodiment, the dummy gate interconnection 38a is connected to the power source potential VDD, and the conductor plug 44c connected to the source region 32S1 of the NMOS transistor 36b is connected to the ground potential VSS. Thus, according to the present embodiment, a decoupling capacitance C1 can be obtained between the dummy gate interconnection 38a and the conductor plug 44c (see FIGS. 26A to 26D).

In the present embodiment, the dummy gate interconnection 38a is connected to the power source potential VDD, and a part of the ground line 50b is formed in parallel with the dummy gate interconnection 38a, whereby a decoupling capacitance C2 can be obtained between the dummy gate interconnection 38a and the ground line 50b (see FIGS. 26A to 26D).

In the present embodiment, the dummy gate interconnection 38a is connected to the power source potential VDD and another part of the ground line 50b crosses the dummy gate interconnection 38a, whereby a decoupling capacitance C3 can be obtained between the dummy gate electrode 38a and the ground line 50b (see FIGS. 26A to 26D).

In the present embodiment, the dummy gate interconnection 38c is connected to the ground potential VSS, and the conductor plug 44f connected to the source region 28S2 of the PMOS transistor 34b is connected to the power source potential VDD. Thus, according to the present embodiment, a decoupling capacitance C4 can be obtained between the dummy gate interconnection 38c and the conductor plug 44f (see FIGS. 26A to 26D).

In the present embodiment, the dummy gate interconnection 38c is connected to the ground potential VSS, and a part of the power source line 50a is formed in parallel with the dummy gate interconnection 38c, whereby a decoupling capacitance C5 can be obtained between the dummy gate interconnection 38c and the power source line 50a (see FIGS. 26A to 26D).

In the present embodiment, the dummy gate interconnection 38c is connected to the ground potential VSS, and another part of the power source line 50a crosses the dummy gate interconnection 38c, whereby a decoupling capacitance C6 can be obtained between the dummy gate electrode 38c and the power source line 50a (see FIGS. 26A to 26D).

As described above, in the present embodiment as well, the decoupling capacitances are formed in the unit cells 6a, 6b, which makes it unnecessary to provide decoupling capacitors of a large opposed area separate from the unit cells 6a, 6b. Even when decoupling capacitors are provided separate from the unit cells 6a, 6b, the area necessary to for such decoupling capacitors can be small. Thus, in the present embodiment as well, the semiconductor device can be downsized.

In the present embodiment as well, the dummy gate interconnection 38b positioned on the side of the drain regions 28D1, 28D2, 32D1, 32D2 of the transistors 34a, 34b, 36a, 36b are electrically floating. Thus, the capacitive coupling of the conductor plugs 44b, 44d, 44e, 44g connected to the drain regions 28D1, 28D2, 32D1, 32D2 with the dummy gate interconnection 38b can be prevented. Thus, in the present embodiment as well, signal delay in the signal lines 50c, 50d electrically connected to the drain regions 28D1, 28D2, 32D1, 32D2 can be prevented.

### [f] Sixth Embodiment

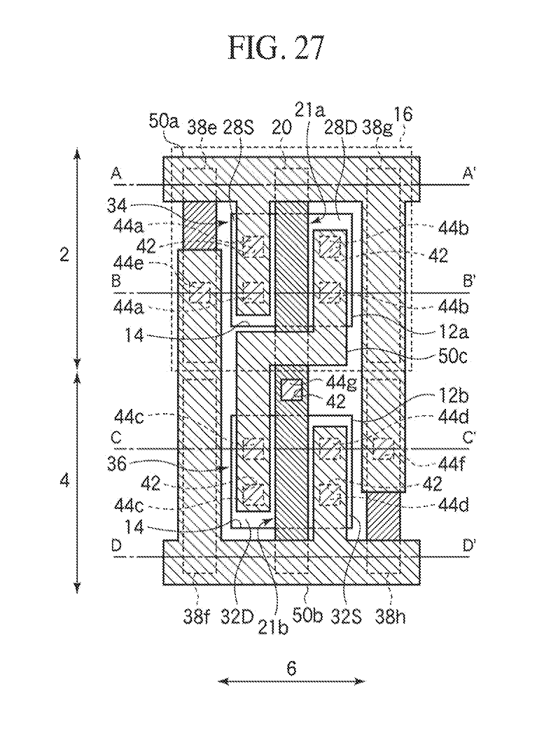

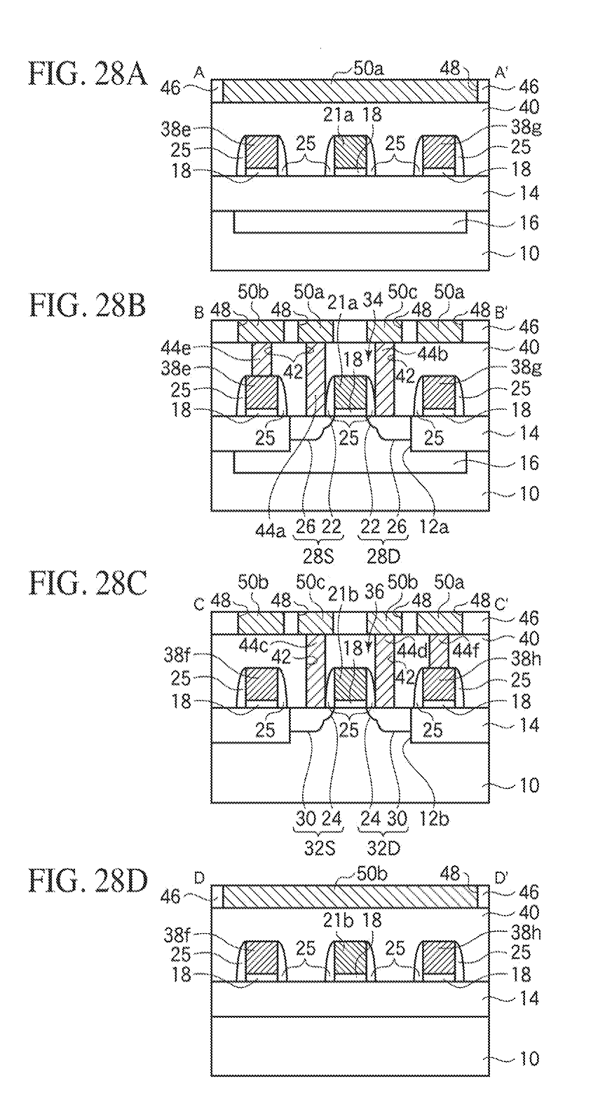

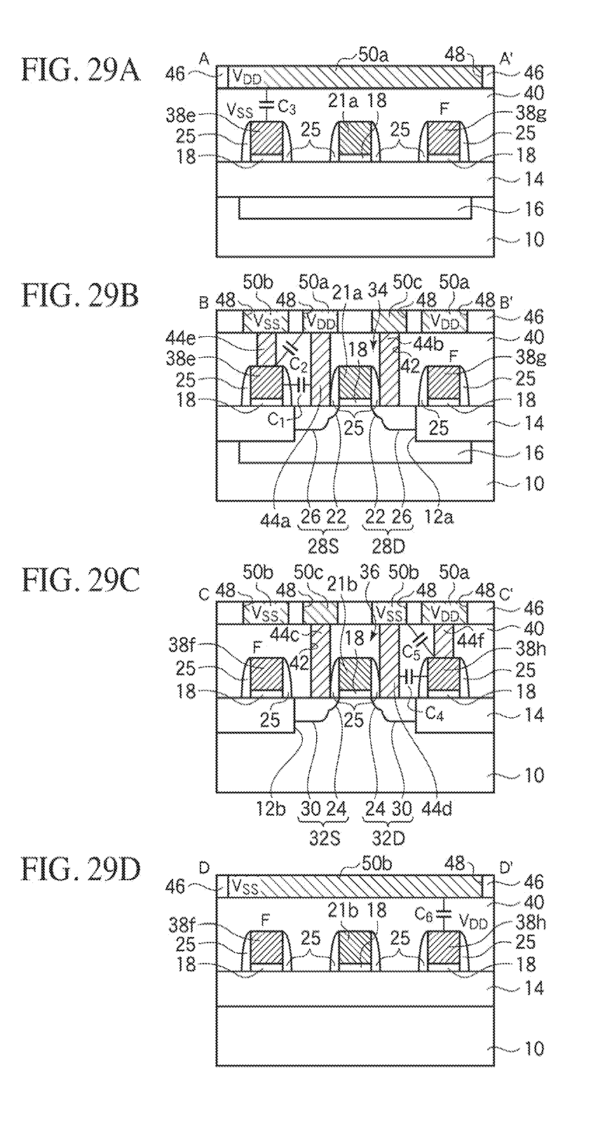

The semiconductor device according to a sixth embodiment will be described with reference to FIGS. 27 to 29D. FIG. 27 is a plan view of the semiconductor device according to the present embodiment. FIGS. 28A to 28D are sectional views of the semiconductor device according to the present embodiment (Part 1). FIGS. 29A to 29D are sectional views of the semiconductor device according to the present embodiment (Part 2). FIGS. 28A and 29A correspond to the A-A′ line section FIG. 27. FIGS. 28B and 29B correspond to the B-B′ line section of FIG. 27. FIGS. 28C and 29C correspond to the C-C′ line section of FIG. 27. FIGS. 28D and 29D correspond to the D-D′ line section of FIG. 27. The same members of the present embodiment as those of the semiconductor device according to the first to the fifth embodiment and its manufacturing method illustrated in FIGS. 1 to 26D are represented by the same reference numbers not repeat or to simplify the description.

In the semiconductor device according to the present embodiment, the dummy gate electrodes 38e, 38g formed respectively along the gate electrode 21a and the dummy gate electrodes 38f, 38h formed along the gate electrode 21b are respectively separated from each other.

In the device region 12a left of the gate electrode 21a of the PMOS transistor 34 as viewed in the drawing, the source region 28S of the extension source/drain structure is formed. In the device region 12a right of the gate electrode 21a of the PMOS transistor 34 as viewed in the drawing, the drain region 28D of the extension source/drain structure is formed.

In the device region 12b left of the gate electrode 21b of the NMOS transistor 36, the drain region 32D of the extension source/drain structure is formed. In the device region 12b right of the gate electrode 21b of the NMOS transistor 36, the source region 32S of the extension source/drain structure is formed.

As described above, in the present embodiment, the source region 28S of the PMOS transistor 34 is positioned left of the gate electrode 21a as viewed in the drawing, but the source region 32S of the NMOS transistor 36 is positioned right of the gate electrode 21b as viewed in the drawing. The drain region 28D of the PMOS transistor 34 is positioned right of the gate electrode 21a as viewed in the drawing, and the drain region 32D of the NMOS transistor 36 is positioned left of the gate electrode 21b as viewed in the drawing.

On the device isolation region 14 left of the device region 12a as viewed in the drawing, the dummy gate electrode (dummy gate pattern, dummy pattern, pattern) 38e is formed in parallel with the gate electrode 21a of the PMOS transistor 34. On the device isolation region 14 right of the device region 12a as viewed in the drawing, the dummy gate electrode (dummy gate pattern, dummy pattern, pattern) 38g is formed in parallel with the gate electrode 21a of the PMOS transistor 34.

On the device isolation region 14 left of the device region 12b as viewed in the drawing, the dummy gate electrode (dummy gate pattern, dummy pattern, pattern) 38f is formed in parallel with the gate electrode 21b of the NMOS transistor 36. On the device isolation region 14 right of the device region 12b as viewed in the drawing, the dummy gate electrode (dummy gate pattern, dummy pattern, pattern) 38h is formed in parallel with the gate electrode 21b of the NMOS transistor 36.

The dummy gate electrode 38e and the dummy gate electrode 38f are separated from each other. The dummy gate electrode 38g and the dummy gate electrode 38h are separated from each other.

In the inter-layer insulation film 40, the conductor plug 44a connected to the source region 28S of the PMOS transistor 34 is buried. In the inter-layer insulation film 40, the conductor plug 44b connected to the drain region 28D of the PMOS transistor 34 is buried. In the inter-layer insulation film 40, the conductor plug 44c connected to the drain region 32D of the NMOS transistor 36 is buried. In the inter-layer insulation film 40, the conductor plug 44d connected to the source region 32S of the NMOS transistor 36 is buried. In the inter-layer insulation film 40, the conductor plug 44e connected to the dummy gate electrode 38e is buried. In the inter-layer insulation film 40, the conductor plug 44g connected to the dummy gate electrode 38h is buried. In the inter-layer insulation film 40, the conductor plug 44f connected to the gate interconnection 20 near the border between the PMOS transistor formed region 2 and the NMOS transistor formed region 4 is buried.

The power source line 50a is electrically connected to the source region 28S of the PMOS transistor 34 via the conductor plug 44a. The power source line 50a is electrically connected to the dummy gate electrode 38h via the conductor plug 44f. A part of the power source line 50a is formed in parallel with the dummy gate interconnection 38e. Another part of the power source line 50a crosses the dummy gate electrode 38e. The power source line 50a is connected to, e.g., the power source potential VDD (see FIGS. 29A to 29D).

The ground line 50b is electrically connected to the source region 32S of the NMOS transistor 36 via the conductor plug 44d. The ground line 50b is electrically connected to the dummy gate electrode 38e via the conductor plug 44e. The ground line 50b is to be connected to, e.g., the ground potential VSS (see FIGS. 29A to 29D).

The signal line 50c is electrically connected to the drain region 28D of the PMOS transistor 34 via the conductor plug 44b and is electrically connected to the drain region 32D of the NMOS transistor 36 via the conductor plug 44c.

The dummy gate electrode 38g positioned right of the gate electrode 21a of the PMOS transistor 34 as viewed in the drawing is electrically floating. The dummy gate electrode 38f positioned left of the gate electrode 21b of the NMOS transistor 36 as viewed in the drawing is electrically floating.

Thus, the semiconductor device according to the present embodiment is formed.

According to the present embodiment, the dummy gate electrode 38e connected to the ground potential VSS, and the conductor plug 44a connected to the source region 28S of the PMOS transistor 34 is connected to the power source potential VDD. Thus, according to the present embodiment, a decoupling capacitance C1 can be obtained between the dummy gate electrode 38e and the conductor plug 44a (see FIGS. 29A to 29D).

The dummy gate electrode 38e is connected to the ground potential VSS, and a part of the power source line 50a is formed in parallel with the dummy gate electrode 38e. A decoupling capacitance C2 can be obtained between the dummy gate electrode 38e and the power source line 50a (see FIGS. 29A to 29D).

The dummy gate electrode 38e is connected to the ground potential VSS, and another part of the power source line 50a crosses the dummy gate electrode 38e. Thus, a decoupling capacitance C3 can be obtained between the dummy gate electrode 38e and the power source line 50a (see FIGS. 29A to 29D).

According to the present embodiment, the dummy gate electrode 38h is connected to the power source potential VDD, and the conductor plug 44d connected to the source region 32S of the NMOS transistor 36 is connected to the ground potential VSS. Thus, according to the present embodiment, a decoupling capacitance C4 can be obtained between the dummy gate electrode 38h and the conductor plug 44d (see FIGS. 29A to 29D).

The dummy gate electrode 38h is connected to the power source potential VDD, and a part of the ground line 50b is formed in parallel with the dummy gate electrode 38h. Thus, a decoupling capacitance C5 can be obtained between the dummy gate electrode 38h and the ground line 50b (see FIGS. 29A to 29D).

The dummy gate electrode 38h is connected to the power source potential VDD, and another part of the ground line 50b crosses the dummy gate electrode 38h. Thus, a decoupling capacitance C6 can be obtained between the dummy gate electrode 38h and the ground line 50b (see FIGS. 29A to 29D).

As described above, the source region 28S of the PMOS transistor 34 may be positioned left of the gate electrode 21a as viewed in the drawing, and the source region 32S of the NMOS transistor 36 may be positioned right of the gate electrode 21b as viewed in the drawing. The drain region 28D of the PMOS transistor 34 may be positioned right of the gate electrode 21a as viewed in the drawing, and the drain region 32D of the NMOS transistor 36 is positioned left of the gate electrode 21b as viewed in the drawing.

According to the present embodiment, the dummy gate electrode 38e and the dummy gate electrode 38f are separated from each other, whereby the dummy gate interconnection 38e can be connected to the ground potential VSS, and the dummy gate interconnection 38f can be electrically floating. The dummy gate electrode 38g and the dummy gate electrode 38h are separated from each other, whereby the dummy gate electrode 38h can be connected to the power source potential VDD, and the dummy gate electrode 38g can be electrically floating. Thus, the capacitive coupling of the conductor plugs 44b, 44c connected to the drain regions 28D, 32D with the dummy gate electrodes 38g, 38f can be prevented, and signal delay can be prevented.

According to the present embodiment, many decoupling capacitances C1-C6 can be obtained in one unit cell 6. Thus, according to the present embodiment, the semiconductor device can have better electric characteristics.

### [g] Seventh Embodiment

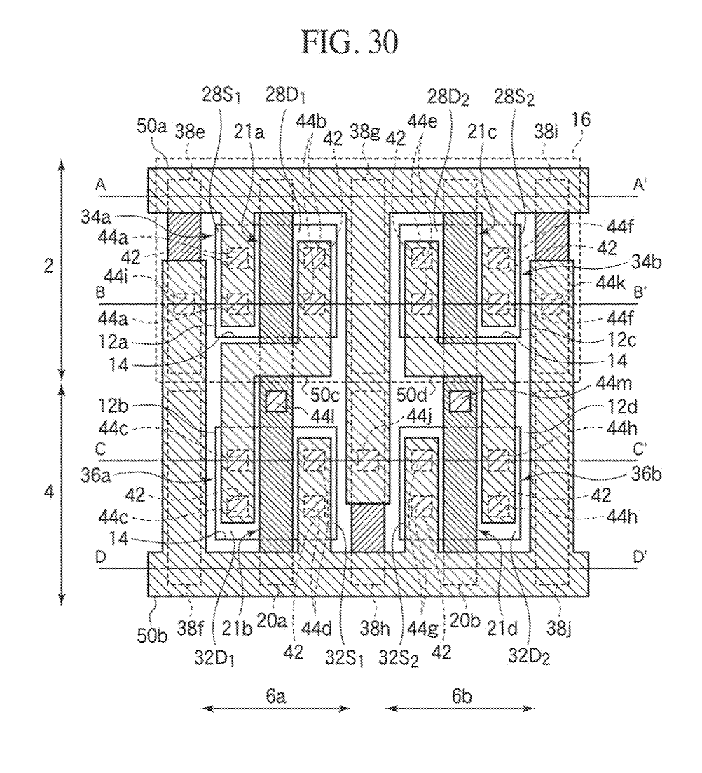

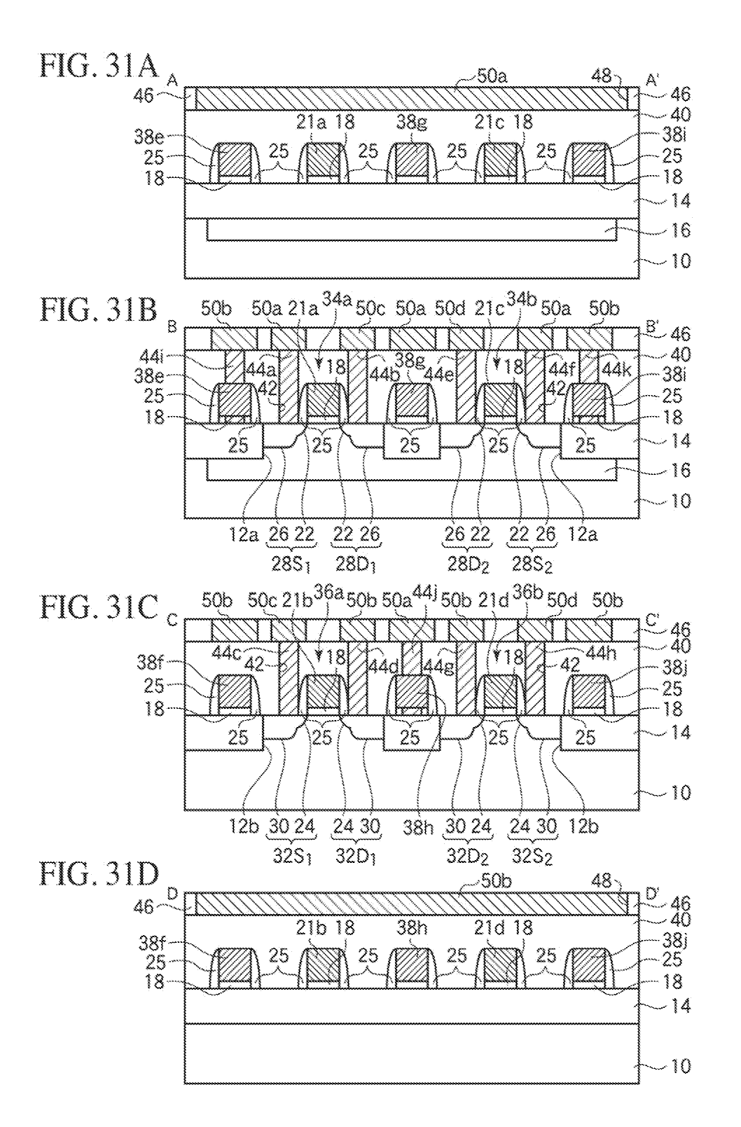

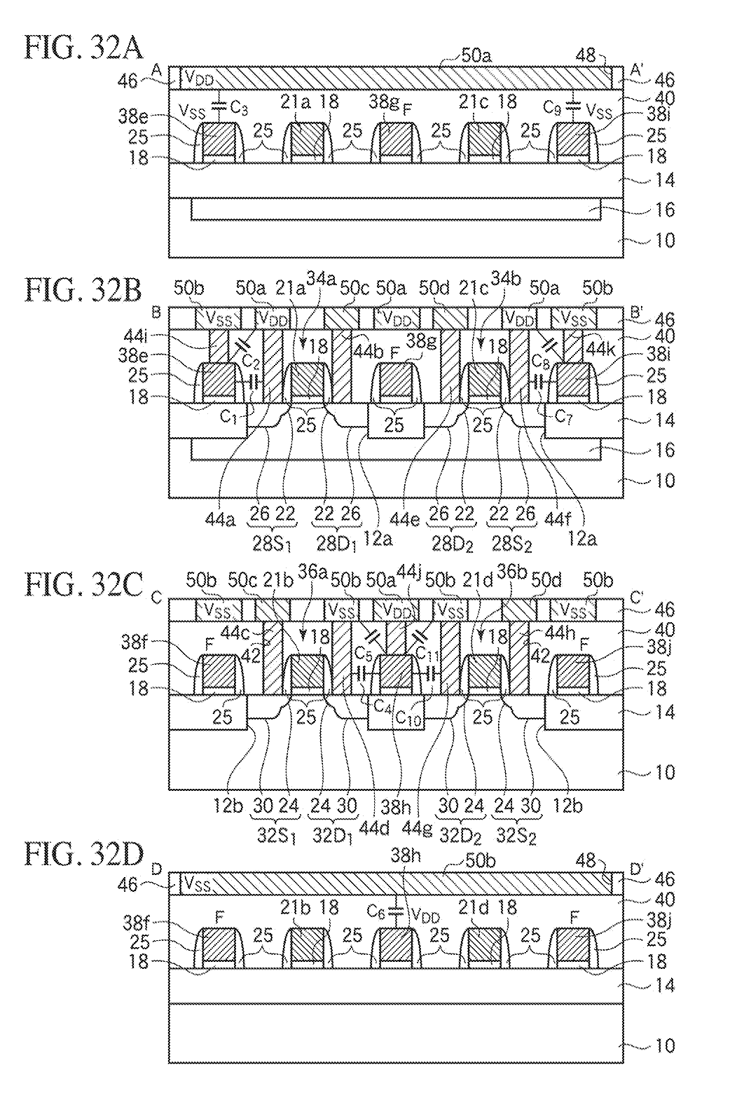

The semiconductor device according to a seventh embodiment will be described with reference to FIGS. 30 to 32D. FIG. 30 is a plan view of the semiconductor device according to the present embodiment. FIGS. 31A to 31D is sectional views of the semiconductor device according to the present embodiment (Part 1). FIGS. 32A to 32D is sectional views of the semiconductor device according to the present embodiment (Part 2). FIGS. 31A and 32A correspond to the A-A′ line section of FIG. 30. FIGS. 31B and 32B correspond to the B-B′ line section of FIG. 30. FIGS. 31C and 32C correspond to the C-C′ line section of FIG. 30. FIGS. 31D and 32D correspond to the D-D′ line section of FIG. 30. The same members of the present embodiment as those of the semiconductor device according to the first to the sixth embodiment and its manufacturing method illustrated in FIGS. 1 to 29D are represented by the same reference numbers not to repeat or to simplify the description.

In the semiconductor device according to the present embodiment, two unit cells 6a, 6b are formed adjacent to each other, and the dummy gate electrodes 38e, 38g, 39i and the dummy gate electrodes 38f, 38h, 38j are respectively separated from each other.

In the device region 12a left of the gate electrode 21a of the PMOS transistor 34a as viewed in the drawing, the source region 28S1 of the extension source/drain structure is formed. In the device region 12a right of the gate electrode 21a of the PMOS transistor 34a as viewed in the drawing, the drain region 28D1 of the extension source/drain structure is formed.

In the device region 12b left of the gate electrode 21b of the NMOS transistor 36a as viewed in the drawing, the drain region 32D1 of the extension source/drain structure is formed. In the device region 12b right of the gate electrode 21b of the NMOS transistor 36a as viewed in the drawing, the source region 32S1 of the extension source/drain structure is formed.

In the device region 12c left of the gate electrode 21c of the PMOS transistor 34b as viewed in the drawing, the drain region 28D2 of the extension source/drain structure is formed. In the device region 12c right of the gate electrode 21c of the PMOS transistor 34b as viewed in the drawing, the source region 28S2 of the extension source/drain structure is formed.

In the device region 12d left of the gate electrode 21d of the NMOS transistor 36b as viewed in the drawing, the source region 32S2 of the extension source/drain structure is formed. In the device region 12d right of the gate electrode 21d of the NMOS transistor 36b as viewed in the drawing, the drain region 32D2 of the extension source/drain structure is formed.

As described above, in the present embodiment, the source region 28S1 of the PMOS transistor 34a is positioned left of the gate electrode 21a as viewed in the drawing, and the source region 32S1 of the NMOS transistor 36a is positioned right of the gate electrode 21b as viewed in the drawing. The drain region 28D1 of the PMOS transistor 34a is positioned right of the gate electrode 21a as viewed in the drawing, and the drain region 32D1 of the NMOS transistor 36a is positioned left of the gate electrode 21b as viewed in the drawing.

In the present embodiment, the source region 28S2 of the PMOS transistor 34b is positioned right of the gate electrode 21c as viewed in the drawing, and the source region 32S2 of the NMOS transistor 36b is positioned left of the gate electrode 21d as viewed in the drawing. The drain region 28D2 of the PMOS transistor 34b is positioned left of the gate electrode 21c as viewed in the drawing, and the drain region 32D2 of the NMOS transistor 36b is positioned right of the gate electrode 21d as viewed in the drawing.

On the device isolation region 14 left of the device region 12a as viewed in the drawing, the dummy gate electrode 38e is formed in parallel with the gate electrode 21a of the PMOS transistor 34a. On the device isolation region 14 left of the device region 12b as viewed in the drawing, the dummy gate electrode 38f is formed in parallel with the gate electrode 21b of the NMOS transistor 36a.

On the device isolation region 14 between the device region 12a and the device region 12c, the dummy gate electrode 38g is formed in parallel with the gate electrodes 21a, 21c. On the device isolation region 14 between the device region 12b and the device region 12d, the dummy gate electrode 38h is formed in parallel with the gate electrodes 21b, 21d.

On the device isolation region 14 right of the device region 12c as viewed in the drawing, the dummy gate electrode (dummy gate pattern, dummy pattern, pattern) 38i is formed in parallel with the gate electrode 21c of the PMOS transistor 34b. On the device isolation region 14 right of the device region 12d as viewed in the drawing, the dummy gate electrode (dummy gate pattern, dummy pattern, pattern) 38j is formed in parallel with the gate electrode 21d of the NMOS transistor 36b.

The dummy gate electrode 38e and the dummy gate electrode 38f are separated from each other. The dummy gate electrode 38g and the dummy gate electrode 38h are separated from each other. The dummy gate electrode 38i and the dummy gate electrode 38j are separated from each other.

In the inter-layer insulation film 40, the conductor plug 44a connected to the source region 28S1 of the PMOS transistor 34a is buried. In the inter-layer insulation film 40, the conductor plug 44b connected to the drain region 28D1 of the PMOS transistor 34a is buried in. In the inter-layer insulation film 40, the conductor plug 44c connected to the drain region 32D1 of the NMOS transistor 36a is buried. In the inter-layer insulation film 40, the conductor plug 44d connected to the source region 32S1 of the NMOS transistor 36a is buried.

In the inter-layer insulation film 40, the conductor plug 44e connected to the drain region 28D2 of the PMOS transistor 34b is buried. In the inter-layer insulation film 40, the conductor plug 44f connected to the source region 28S2 of the PMOS transistor 34b is buried. In the inter-layer insulation film 40, the conductor plug 44g connected to the source region 32S2 of the NMOS transistor 36b is buried. In the inter-layer insulation film 40, the conductor plug 44h connected to the drain region 32D2 of the NMOS transistor 36b is buried.

In the inter-layer insulation film 40, the conductor plug 44i connected to the dummy gate electrode 38e is buried. In the inter-layer insulation film 40, the conductor plug 44j connected to the dummy gate electrode 38h is buried. In the inter-layer insulation film 40, the conductor plug 44k connected to the dummy gate electrode 38i is buried.

In the inter-layer insulation film 40, the conductor plug 44l connected to the gate interconnection 20a near the border between the PMOS transistor formed region 2 and the NMOS transistor formed region 4 is buried. In the inter-layer insulation film 40, the conductor plug 44m connected to the gate interconnection 20b near the border between the PMOS transistor formed region 2 and NMOS transistor formed region 4 is buried.

The power source line 50a is electrically connected to the source region 28S1 of the PMOS transistor 34a via the conductor plug 44a. The power source line 50a is electrically connected to the source region 28S2 of the PMOS transistor 34b via the conductor plug 44f. The power source line 50a is electrically connected to the dummy gate electrode 38h via the conductor plug 44j. A part of the power source line 50a is formed in parallel with the dummy gate interconnections 38e, 38i. Another part of the power source line 50a crosses the dummy gate electrodes 38e, 38i. The power source line 50a is to be connected to, e.g., the power source potential VDD (see FIGS. 32A to 32D).

The ground line 50b is electrically connected to the source region 32S1 of the NMOS transistor 36a via the conductor plug 44d. The ground line 50b is electrically connected to the source region 32S2 of the NMOS transistor 36b via the conductor plug 44g. The ground line 50b is electrically connected to the dummy gate electrode 38e via the conductor plug 44i. The ground line 50b is electrically connected to the dummy gate electrode 38i via the conductor plug 44k. The ground line 50b is to be connected to, e.g., the ground potential VSS (see FIGS. 32A to 32D).

The signal line 50c is electrically connected to the drain region 28D1 of the PMOS transistor 34a via the conductor plug 44b and electrically connected to the drain region 32D1 of the NMOS transistor 36a via the conductor plug 44c.

The signal line 50d is electrically connected to the drain region 28D2 of the PMOS transistor 34b via the conductor plug 44e and electrically connected to the drain region 32D2 of the NMOS transistor 36b via the conductor plug 44h.

The dummy gate electrode 38g formed on the device isolation region 14 between the device region 12a and the source region 12c is electrically floating. The dummy gate electrode 38f formed on the device isolation region 14 left of the device region 12b as viewed in the drawing is electrically floating. The dummy gate electrode 38j formed on the device isolation region 14 right of the device region 12d as viewed in the drawing is electrically floating.

Thus, the semiconductor device according to the present embodiment is formed.

According to the present embodiment, the dummy gate electrode 38e is connected to the ground potential VSS and the conductor plug 44a connected to the source region 28S1 of the PMOS transistor 34a is connected to the power source potential VDD. Thus, according to the present embodiment, a decoupling capacitance C1 can be obtained between the dummy gate electrode 38e and the conductor plug 44a (see FIGS. 32A to 32D).

The dummy gate electrode 38e is connected to the ground potential VSS and a part of the power source line 50a is formed in parallel with the dummy gate electrode 38e. Thus, a decoupling capacitance C2 can be obtained between the dummy gate electrode 38e and the power source line 50a (see FIGS. 32A to 32D).

The dummy gate electrode 38e is connected to the ground potential VSS, and another part of the power source line 50a crosses the dummy gate electrode 38e. Thus, a decoupling capacitance C3 can be obtained between the dummy gate electrode 38e and the power source line 50a (see FIGS. 32A to 32D).

According to the present embodiment, the dummy gate electrode 38h is connected to the power source potential VDD, and the conductor plug 44d connected to the source region 32S1 of the NMOS transistor 36a is connected to the ground potential VSS. Thus, a decoupling capacitance C4 can be obtained between the dummy gate electrode 38h and the conductor plug 44d (see FIGS. 32A to 32D).

The dummy gate electrode 38h is connected to the power source potential VDD, and a part of the ground line 50b crosses the dummy gate electrode 38h. Thus, a decoupling capacitance C5 can be obtained between the dummy gate electrode 38h and the ground line 50b (see FIGS. 32A to 32D).

The dummy gate electrode 38h is connected to the power source potential VDD, and another part of the ground line 50b crosses the dummy gate electrode 38h. Thus, a decoupling capacitance C6 can be obtained between the dummy gate electrode 38h and the ground line 50b (see FIGS. 32A to 32D).

According to the present embodiment, the dummy gate electrode 38i is connected to the ground potential VSS, and the conductor plug 44f connected to the source region 28S2 of the PMOS transistor 34b is connected to the power source potential VDD. Thus, according to the present embodiment, a decoupling capacitance C7 can be obtained between the dummy gate electrode 38i and the conductor plug 44f (see FIGS. 32A to 32D).

The dummy gate electrode 38i is connected to the ground potential VSS, and a part of the power source line 50a is formed in parallel with the dummy gate electrode 38i. Thus, a decoupling capacitance C8 can be obtained between the dummy gate electrode 38i and the power source line 50a (see FIGS. 32A to 32D).

The dummy gate electrode 38e is connected to the ground potential VSS, and another part of the power source line 50a crosses the dummy gate electrode 38i. Thus, a decoupling capacitance C9 can be obtained between the dummy gate electrode 38i and the power source line 50a (see FIGS. 32A to 32D).

According to the present embodiment, the dummy gate electrode 38h is connected to the power source potential VDD, and the conductor plug 44g connected to the source region 32S2 of the NMOS transistor 36b is connected to the ground potential VSS. Thus, according to the present embodiment, a decoupling capacitance C10 can be obtained between the dummy gate electrode 38h and the conductor plug 44g (see FIGS. 32A to 32D).

The dummy gate electrode 38h is connected to the power source potential VDD, and a part of the ground line 50b is formed in parallel with the dummy gate electrode 38h. Thus, a decoupling capacitance C11 can be obtained between the dummy gate electrode 38h and the ground line 50b (see FIGS. 32A to 32D).

As described above, the source region 28S1 of the PMOS transistor 34a may be positioned left of the gate electrode 21a as viewed in the drawing, and the source region 32S1 of the NMOS transistor 36a may be positioned right of the gate electrode 21b as viewed in the drawing. The drain region 28D1 of the PMOS transistor 34a may be positioned right of the gate electrode 21a as viewed in the drawing, and the drain region 32D1 of the NMOS transistor 36a may be positioned left of the gate electrode 21b as viewed in the drawing. The source region 28S2 of the PMOS transistor 34b may be positioned right of the gate electrode 21c as viewed in the drawing, and the source region 32S2 of the NMOS transistor 36b may be positioned left of the gate electrode 21d as viewed in the drawing. The drain region 28D2 of the PMOS transistor 34b may be positioned left of the gate electrode 21c, and the drain region 32D2 of the NMOS transistor 36b may be positioned right of the gate electrode 21d as viewed in the drawing.

According to the present embodiment, the dummy gate electrode 38e and the dummy gate electrode 38f is separated from each other, whereby the dummy gate electrode 38e is connected to the ground potential VSS, and the dummy gate electrode 38f can be electrically floating. The dummy gate electrode 38g and the dummy gate electrode 38h are separated from each other, whereby the dummy gate electrode 38h is connected to the power source potential VDD, and the dummy gate electrode 38g can be electrically floating. The dummy gate electrode 38i and the dummy gate electrode 38j are separated from each other, whereby the dummy gate interconnection 38i is connected to the ground potential VSS, and the dummy gate interconnection 38j can be electrically floating. Thus, the capacitive coupling of the conductor plugs 44b, 44c, 44e, 44h connected to the drain regions 28D1, 32D1, 28D2, 32D2 with the dummy gate electrodes 38g, 38f, 38j can be prevented, and signal delay can be prevented.

According to the present embodiment, many decoupling capacitances can be obtained in the respective unit cells 6a, 6b. Thus, the semiconductor device can have better electric characteristics.

### [h] Eighth Embodiment

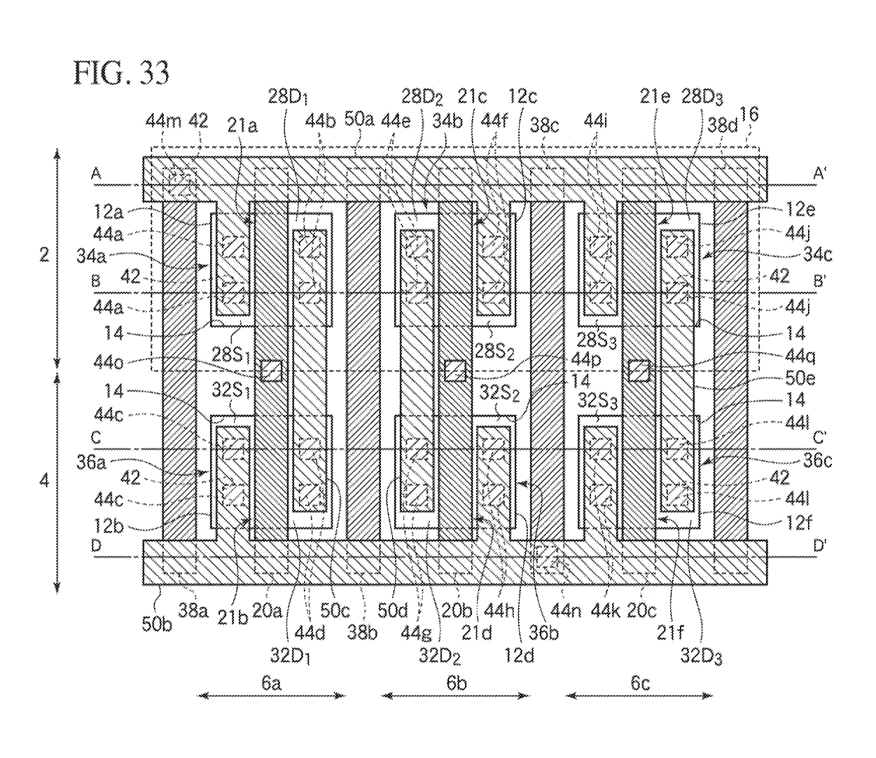

The semiconductor device according to an eighth present embodiment will be described with reference to FIG. 33. FIG. 33 is a plan view of the semiconductor device according to the present embodiment. The same members of the present embodiment as those of the semiconductor device according to the first to the seventh embodiments and its manufacturing method illustrated in FIGS. 1 to 32D are represented by the same reference numbers not to repeat or to simplify the description.

The semiconductor device according to the present embodiment includes a number of the unit cells 6a-6c laid out adjacent to each other.

In FIG. 33, three unit cells 6a-6c of a number of the units cells laid out adjacent to each other are illustrated.

As illustrated in FIG. 33, in the semiconductor substrate 10, the device isolation regions 14 defining the device regions 12a-12f are formed. The device regions 12a, 12c, 12e are formed in the PMOS transistor formed region 2. The device regions 12b, 12c, 12e are formed in the NMOS transistor formed region 4. The device region 12a is positioned on the left side as viewed in the drawing; the device region 12c is positioned right of the device region 12a as viewed in the drawing; and the device region 12e is positioned right of the device region 12c as viewed in the drawing. The device region 12b is position on the left side as viewed in the drawing; the device region 12d is positioned right of the device region 12b as viewed in the drawing; and the device region 12f is positioned right of the device region 12d as viewed in the drawing.

In the semiconductor substrate 10 in the PMOS transistor formed region 2, the N-type well 16 is formed.

On the semiconductor substrate 10 in the PMOS transistor formed region 2, the gate electrodes 21a, 21c, 21e are formed with the gate insulation films 18 formed therebetween. On the semiconductor substrate 10 in the NMOS transistor formed region 4, the gate electrodes 21b, 21d, 21f are formed with the gate insulation film 18 formed therebetween.

The gate electrodes 21a and the gate electrode 21b are parts of the gate interconnection 20a formed continuously in the PMOS transistor formed region 2 and the NMOS transistor formed region 4. The gate electrode 21c and the gate electrode 21d are parts of the gate interconnection 20b formed continuously in the PMOS transistor formed region 2 and the NMOS transistor formed region 4. The gate electrode 21e and the gate electrode 21f are parts of the gate interconnection 20c formed continuously in the PMOS transistor formed region 2 and the NMOS transistor formed region 4. The gate interconnections 20a-20c are, e.g., polysilicon film or others.

In the device region 12a left of the gate electrode 21a of the PMOS transistor 34a as viewed in the drawing, the source region 28S1 of the extension source/drain structure is formed. In the device region 12a right of the gate electrode 21a of the PMOS transistor 34a as viewed in the drawing, the drain region 28D1 of the extension source/drain structure is formed.

In the device region 12b left of the gate electrode 21b of the NMOS transistor 36a as viewed in the drawing, the source region 32S1 of the extension source/drain structure is formed. In the device region 12b right of the gate electrode 21b of the NMOS transistor 36a as viewed in the drawing, the drain region 32D1 of the extension source/drain structure is formed.

In the device region 12c left of the gate electrode 21c of the PMOS transistor 34b as viewed in the drawing, the drain region 28D2 of the extension source/drain structure is formed. In the device region 12c right of the gate electrode 21c of the PMOS transistor 34b, the source region 28S2 of the extension source/drain structure is formed.

In the device region 12d left of the gate electrode 21d of the NMOS transistor 36b as viewed in the drawing, the drain region 32D2 of the extension source/drain structure is formed. In the device region 12d right of the gate electrode 21b of the NMOS transistor 36b, the source region 32S2 of the extension source/drain structure is formed.

In the device region 12e left of the gate electrode 21e of the PMOS transistor 34c as viewed in the drawing, the source region 28S3 of the extension source/drain structure is formed. In the device region 12e right of the gate electrode 21e of the PMOS transistor 34c as viewed in the drawing, the drain region 28D3 of the extension source/drain structure is formed.

In the device region 12f left of the gate electrode 21f of the NMOS transistor 36c, the source region 28S3 of the extension source/drain structure is formed. In the device region 12f right of the gate electrode 21f of the NMOS transistor 36c, the drain region 32D3 of the extension source/drain structure is formed.

On the device isolation region 14 left of the gate interconnection 20a as viewed in the drawing, the dummy gate interconnection 38a is formed in parallel with the gate interconnection 20a. The dummy gate interconnection 38a is positioned left of the device regions 12a, 12b as viewed in the drawing.

On the device isolation region 14 between the gate interconnection 20a and the gate interconnection 20b, the dummy gate interconnection 38b is formed in parallel with the gate interconnections 20a, 20b. The dummy gate interconnection 38b is positioned right of the device regions 12a, 12b as viewed in the drawing and left of the device regions 12c, 12d as viewed in the drawing.

On the device isolation region 14 between the gate interconnection 20b and the gate interconnection 20c, the dummy gate interconnection 38c is formed in parallel with the gate interconnections 20b, 20c. The dummy gate interconnection 38c is positioned right of the device regions 12c, 12d as viewed in the drawing, and left of the device regions 12e, 12f as viewed in the drawing.

On the device isolation region 14 right of the gate interconnection 20c as viewed in the drawing, the dummy gate interconnection (dummy gate electrode, dummy gate pattern, dummy pattern, pattern) 38d is formed in parallel with the gate interconnection 20c. The dummy gate interconnection 38d is positioned right of the device regions 12e, 12f as viewed in the drawing.

In the inter-layer insulation film 40, the conductor plug 44a connected to the source region 28S1 of the PMOS transistor 34a is buried. In the inter-layer insulation film 40, the conductor plug 44b connected to the drain region 28D1 of the PMOS transistor 34a is buried.

In the inter-layer insulation film 40, the conductor plug 44c connected to the source region 32S1 of the NMOS transistor 36a is buried. In the inter-layer insulation film 40, the conductor plug 44d connected to the drain region 32D1 of the NMOS transistor 36a is buried.

In the inter-layer insulation film 40, the conductor plug 44e connected to the drain region 28D2 of the PMOS transistor 34b is buried. In the inter-layer insulation film 40, the conductor plug 44f connected to the source region 28S2 of the PMOS transistor 34b is buried.

In the inter-layer insulation film 40, the conductor plug 44g connected to the drain region 32D2 of the NMOS transistor 36b is buried. In the inter-layer insulation film 40, the conductor plug 44h connected to the source region 32S2 of the NMOS transistor 36b is buried.

In the inter-layer insulation film 40, the conductor plug 44i connected to the source region 28S3 of the PMOS transistor 34c is buried. In the inter-layer insulation film 40, the conductor plug 44j connected to the drain region 28D3 of the PMOS transistor 34c is buried.

In the inter-layer insulation film 40, the conductor plug 44k connected to the source region 32S3 of the NMOS transistor 36c is buried. In the inter-layer insulation film 40, the conductor plug 44l connected to the drain region 32D3 of the NMOS transistor 36c is buried.

In the inter-layer insulation film 40, the conductor plug 44m connected to the dummy gate electrode 38a is buried. In the inter-layer insulation film 40, the conductor plug 44n connected to the dummy gate electrode 38c is buried.

In the inter-layer insulation film 40, the conductor plug 44o connected to the gate interconnection 20a near the border between the PMOS transistor formed region 2 and the NMOS transistor formed region 4 is buried. In the inter-layer insulation film 40, the conductor plug 44p connected to the gate interconnection 20b near the border between the PMOS transistor formed region 2 and the NMOS transistor formed region 4 is buried. In the inter-layer insulation film 40, the conductor plug 44q connected to the gate interconnection 20c near the border between the PMOS transistor formed region 2 and the NMOS transistor formed region 4 is buried.

The power source line 50a is electrically connected to the source region 28S1 of the PMOS transistor 34a via the conductor plug 44a. The power source line 50a is electrically connected to the source region 28S2 of the PMOS transistor 34b via the conductor plug 44f. The power source line 50a is electrically connected to the source region 28S3 of the PMOS transistor 34c via the conductor plug 44i. The power source line 50a is electrically connected to the dummy gate electrode 38a via the conductor plug 44m. A part of the power source line 50a is formed in parallel with the dummy gate interconnections 38a, 38c. Another part of the power source line 50a crosses the dummy gate interconnections 38a, 38c. The power source line 50a is to be connected to the power source potential VDD.

The ground line 50b is electrically connected to the source region 32S1 of the NMOS transistor 36a via the conductor plug 44c. The ground line 50b is electrically connected to the source region 32S2 of the NMOS transistor 36b via the conductor plug 44h. The ground line 50b is electrically connected to the source region 32S3 of the NMOS transistor 36c via the conductor plug 44k. The ground line 50b is electrically connected to the dummy gate interconnection 38c via the conductor plug 44n. A part of the ground line 50b is formed in parallel with the dummy gate interconnections 38a, 38c. Another part of the ground line 50b crosses the dummy gate interconnections 38a, 38c. The ground line 50b is to be connected o the ground potential VSS.

The signal line 50c is electrically connected to the drain region 28D1 of the PMOS transistor 34a via the conductor plug 44b and electrically connected to the rain region 32D1 of the NMOS transistor 36a via the conductor plug 44d.

The signal line 50d is electrically connected to the drain region 28D2 of the PMOS transistor 34b via the conductor plug 44e and electrically connected to the drain region 32D2 of the NMOS transistor 36b via the conductor plug 44g.

The signal line 50e is electrically connected to the drain region 28D3 of the PMOS transistor 34c via the conductor plug 44j and electrically connected to the drain region 32D3 of the NMOS transistor 36c via the conductor plug 44l.

The dummy gate interconnection 38b formed on the device isolation region 14 between the gate interconnection 20a and the gate interconnection 20b is electrically floating. The dummy gate interconnection 38d formed on the device isolation region 14 right of the gate interconnection 20c as viewed in the drawing is electrically floating.

Thus, the semiconductor device according to the present embodiment is formed.

As described above, a number of the unit cells 6a-6c may be laid out adjacent to each other.

In the present embodiment as well, decoupling capacitances are formed in the same way as in the semiconductor device according to the fifth embodiment described above with reference to FIGS. 24 to 26D. Thus, in the present embodiment as well, it is not necessary to provide decoupling capacitors of a large opposed area separate from the unit cells 6a-6c. When decoupling capacitors are provided separate from the unit cells 6a-6c, the area necessary to form such decoupling capacitors can be small. Thus, in the present embodiment as well, the semiconductor device can be downsized.

In the present embodiment as well, the dummy gate interconnections 38b, 38d positioned on the side of the drain regions 28D1-28D3, 32D1-32D3 of the transistors 34a-34c, 36a-36b are electrically floating. Thus, the capacitive coupling of the conductor plugs 44b, 44d, 44e, 44g, 44j, 44l connected to the drain regions 28D1-28D3, 32D1-32D3 can be prevented. Thus, in the present embodiment, signal delay can be prevented in the signal lines 50c, 50d, 50e electrically connected to the drain regions 28D1-28D3, 32D1-32D3.

### [i] Ninth Embodiment

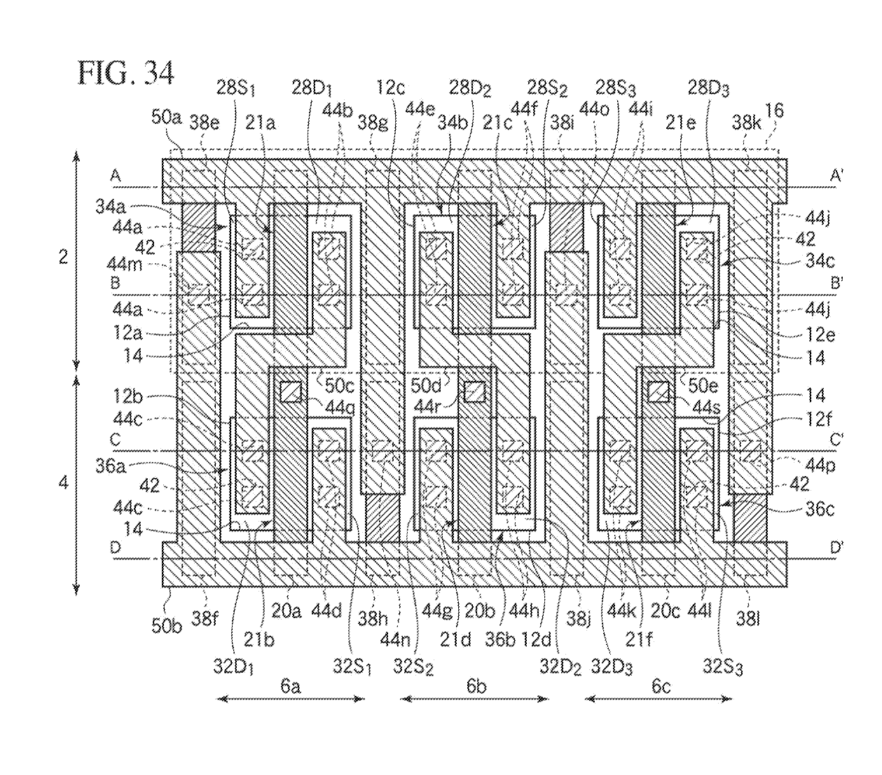

The semiconductor device according to an eighth embodiment will be described with reference to FIG. 34. FIG. 34 is a plan view of the semiconductor device according to the present embodiment. The same members of the present embodiment as those of the semiconductor device according to the first to the eighth embodiments and its manufacturing method illustrated in FIGS. 1 to 33 are represented by the same reference numbers not to repeat or to simplify the description.

The semiconductor device according to the present embodiment includes a number of unit cells formed adjacent to each other, and the dummy gate electrodes 38e, 38g, 38i, 38k and the dummy gate electrodes 38f, 38h, 38j, 38l separated from each other.

In the device region 12a left of the gate electrode 21a of the PMOS transistor 34a as viewed in the drawing, the source region 28S1 of the extension source/drain structure is formed. In the device region 12a right of the gate electrode 21a of the PMOS transistor 34a as viewed in the drawing, the drain region 28D1 of the extension source/drain structure is formed.

In the device region 12b left of the gate electrode 21b of the NMOS transistor 36a as viewed in the drawing, the drain region 32D1 of the extension source/drain structure is formed. In the device region 12b right of the gate electrode 21b of the NMOS transistor 36a as viewed in the drawing, the source region 32S1 of the extension source/drain structure is formed.

In the device region 12c left of the gate electrode 21c of the PMOS transistor 34b as viewed in the drawing, the drain region 28D2 of the extension source/drain structure is formed. In the device region 12c right of the gate electrode 21c of the PMOS transistor 34b as viewed in the drawing, the source region 28S2 of the extension source/drain structure is formed.

In the device region 12d left of the gate electrode 21d of the NMOS transistor 36b as viewed in the drawing, the source region 32S2 of the extension source/drain structure is formed. In the device region 12d right of the gate electrode 21d of the NMOS transistor 36b as viewed in the drawing, the drain region 32D2 of the extension source/drain structure is formed.

In the device region 12e left of the gate electrode 21e of the PMOS transistor 34c as viewed in the drawing, the source region 28S3 of the extension source/drain structure is formed. In the device region 12e right of the gate electrode 21f of the PMOS transistor 34c as viewed in the drawing, the drain region 28D3 of the extension source/drain structure is formed.

In the device region 12f left of the gate electrode 21f of the NMOS transistor 36c as viewed in the drawing, the drain region 32D3 of the extension source/drain structure is formed. In the device region 12f right of the gate electrode 21f of the NMOS transistor 36c, the source region 32S3 of the extension source/drain structure is formed.

As described above, in the present embodiment, the source region 28S1 of the PMOS transistor 34a is positioned left of the gate electrode 21a as viewed in the drawing, and the source region 32S1 of the NMOS transistor 36a is positioned right of the gate electrode 21b as viewed in the drawing. The drain region 28D1 of the PMOS transistor 34a is positioned right of the gate electrode 21a as viewed in the drawing, and the drain region 32D1 of the NMOS transistor 36a is positioned left of the gate electrode 21b as viewed in the drawing.

In the present embodiment, the source region 28S2 of the PMOS transistor 34b is positioned right of the gate electrode 21c as viewed in the drawing, and the source region 32S2 of the NMOS transistor 36b is positioned left of the gate electrode 21d as viewed in the drawing. The drain region 28D2 of the PMOS transistor 34b is positioned left of the gate electrode 21c as viewed in the drawing, and the drain region 32D2 of the NMOS transistor 36b is positioned right of the gate electrode 21d as viewed in the drawing.

In the present embodiment, the source region 28S3 of the PMOS transistor 34c is positioned left of the gate electrode 21e as viewed in the drawing, and the source region 32S3 of the NMOS transistor 36a is positioned right of the gate electrode 21f as viewed in the drawing. The drain region 28D3 of the PMOS transistor 34c is positioned right of the gate electrode 21e as viewed in the drawing, and the drain region 32D3 of the NMOS transistor 36c is positioned left of the gate electrode 21f as view in the drawing.

On the device isolation region 14 left of the device region 12a as viewed in the drawing, the dummy gate electrode 38e is formed in parallel with the gate electrode 21a of the PMOS transistor 34a. On the device isolation region 14 left of the device region 12b as viewed in the drawing, the dummy gate electrode 38f is formed in parallel with the gate electrode 21b of the NMOS transistor 36a as viewed in the drawing.

On the device isolation region 14 between the device region 12a and the device region 12c, the dummy gate electrode 38g is formed in parallel with the gate electrodes 21a, 21c. On the device isolation region 14 between the device region 12b and the device region 12d, the dummy gate electrode 38h is formed in parallel with the gate electrodes 21b, 21d.

On the device isolation region 14 between the device region 12c and the device region 12e, the dummy gate electrode 38i is formed in parallel with the gate electrodes 21c, 21e. On the device isolation region 14 between the device region 12d and the device region 12f, the dummy gate electrode 38j is formed in parallel with the gate electrodes 21d, 21f.

On the device isolation region 14 right of the device region 12e as viewed in the drawing, the dummy gate electrode (dummy gate pattern, dummy pattern, pattern) 38k is formed in parallel with the gate electrode 21e of the PMOS transistor 34c. On the device isolation region 14 right of the device region 12f as viewed in the drawing, the dummy gate electrode (dummy gate pattern, dummy pattern, pattern) 38l is formed in parallel with the gate electrode 21f of the NMOS transistor 36c.

The dummy gate electrode 38e and the dummy gate electrode 38f are separated from each other. The dummy gate electrode 38g and the dummy gate electrode 38h are separated from each other. The dummy gate electrode 38i and the dummy gate electrode 38j are separated from each other. The dummy gate electrode 38k and the dummy gate electrode 38l are separated from each other.

In the inter-layer insulation film 40, the conductor plug 44a connected to the source region 28S1 of the PMOS transistor 34a is buried. In the inter-layer insulation film 40, the conductor plug 44b connected to the drain region 28D1 of the PMOS transistor 34a is buried. In the inter-layer insulation film 40, the conductor plug 44c connected to the drain region 32D1 of the NMOS transistor 36a is buried. In the inter-layer insulation film 40, the conductor plug 44d connected to the source region 32S1 of the NMOS transistor 36a is buried.

In the inter-layer insulation film 40, the conductor plug 44e connected to the drain region 28D2 of the PMOS transistor 34b is buried. In the inter-layer insulation film 40, the conductor plug 44f connected to the source region 28S2 of the PMOS transistor 34b is buried. In the inter-layer insulation film 40, the conductor plug 44g connected to the source region 32S2 of the NMOS transistor 36b is buried. In the inter-layer insulation film 40, the conductor plug 44h connected to the drain region 32D2 of the NMOS transistor 36b is buried.

In the inter-layer insulation film 40, the conductor plug 44i connected to the source region 28S3 of the PMOS transistor 34c is buried. In the inter-layer insulation film 40, the conductor plug 44j connected to the drain region 28D3 of the PMOS transistor 34c is buried. In the inter-layer insulation film 40, the conductor plug 44k connected to the drain region 32D3 of the NMOS transistor 36c is buried. In the inter-layer insulation film 40, the conductor plug 44l connected to the source region 32S3 of the NMOS transistor 36c is buried.

In the inter-layer insulation film 40, the conductor plug 44m connected to the dummy gate electrode 38e is buried. In the inter-layer insulation film 40, the conductor plug 44n connected to the dummy gate electrode 38h is buried. In the inter-layer insulation film 40, the conductor plug 44o connected to the dummy gate electrode 38i is buried. In the inter-layer insulation film 40, the conductor plug 44p connected to the dummy gate electrode 38l is buried.

In the inter-layer insulation film 40, the conductor plug 44q connected to the gate interconnection 20a near the border between the PMOS transistor formed region 2 and the NMOS transistor formed region 4 is buried. In the inter-layer insulation film 40, the conductor plug 44r connected to the gate interconnection 20b near the border between the PMOS transistor formed region 2 and the NMOS transistor formed region 4 is buried. In the inter-layer insulation film 40, the conductor plug 44s connected to the gate interconnection 20c near the border between the PMOS transistor formed region 2 and the NMOS transistor formed region 4 is buried.

The power source line 50a is electrically connected to the source region 28S1 of the PMOS transistor 34a via the conductor plug 44a. The power source line 50a is electrically connected to the source region 28S2 of the PMOS transistor 34b via the conductor plug 44f. The power source line 50a is electrically connected to the source region 28S3 of the PMOS transistor 34c via the conductor plug 44i. The power source line 50a is electrically connected to the dummy gate electrode 38h via the conductor plug 44n. The power source line 50a is electrically connected to the dummy gate electrode 38l via the conductor plug 44p. A part of the power source line 50a is formed in parallel with the dummy gate electrodes 38e, 38i. Another part of the power source line 50a crosses the dummy electrodes 38e, 38i. The power source line 50a is to be connected to, e.g., the power source potential VDD.

The ground line 50b is electrically connected to the source region 32S1 of the NMOS transistor 36a via the conductor plug 44d. The ground line 50b is electrically connected to the source region 32S2 of the NMOS transistor 36b via the conductor plug 44g. The ground line 50b is electrically connected to the source region 32S3 of the NMOS transistor 36c via the conductor plug 44l. The ground line 50b is electrically connected to the dummy gate electrode 38e via the conductor plug 44m. The ground line 50b is electrically connected to the dummy gate electrode 38i via the conductor plug 44o. The ground line 50b is to be connected to, e.g., the ground potential VSS.

The signal line 50c is electrically connected to the drain region 28D1 of the PMOS transistor 34a via the conductor plug 44b and electrically connected to the drain region 32D1 of the NMOS transistor 36a via the conductor plug 44c.

The signal line 50d is electrically connected to the drain region 28D2 of the PMOS transistor 34b via the conductor plug 44e and electrically connected to the drain region 32D2 of the NMOS transistor 36b via the conductor plug 44h.

The signal line 50e is electrically connected to the drain region 28D3 of the PMOS transistor 34c via the conductor plug 44j and electrically connected to the drain region 32D3 of the NMOS transistor 36c via the conductor plug 44k.

The dummy gate electrode 38g formed on the device isolation region 14 between the device region 12a and the source region 12c is electrically floating. The dummy gate electrode 38f formed on the device isolation region 14 left of the device region 12b as viewed in the drawing is electrically floating. The dummy gate interconnection 38j formed on the device isolation region 14 between the device region 12d and the device region 12f is electrically floating. The dummy gate electrode 38k formed on the device isolation region 14 right of the device region 12e as viewed in the drawing is electrically floating.

Thus, the semiconductor device according to the present embodiment is formed.

As described above, a number of the unit cells 6a-6c may be laid out adjacent to each other.

In the present embodiment as well, in the same way as in the semiconductor device according to the seventh embodiment described above with reference to FIGS. 30 to 32D, decoupling capacitances are formed. Thus, according to the present embodiment, it is unnecessary to provide decoupling capacitors of a large opposed area separate from the unit cells 6a-6c. Even when decoupling capacitors are provided separate from the unit cells 6a-6c, the area necessary to form such decoupling capacitors can be small. Thus, in the present embodiment as well, the semiconductor device can be downsized.

### Modified Embodiments

The present invention is not limited to the embodiments described above and can cover other various modifications.

For example, in the above-described embodiments, the case that the unit cells 6, 6a-6c are CMOS inverter circuits is described. The unit cells 6, 6a-6c are not limited to CMOS inverter circuits. The unit cells 6, 6a-6c may be, e.g., NAND circuits, NOR circuits or others.

In the above-described embodiments, the gate width of the PMOS transistor 34, and the gate width of the NMOS transistor 36 are the same, but this is not essential. The gate width of the PMOS transistor 34 and the gate width of the NMOS transistor 36 may be different from each other. For example, the gate width of the PMOS transistor 34 may be larger than the gate width of the NMOS transistor 36. In this case, a number of the conductor plugs 44a, 44b connected to the source/drain regions 28S, 28D may be larger than a number of the conductor plugs 44c, 44d connected to the source/drain regions 32S, 32D of the NMOS transistor 36. In this case, it is preferably to form a decoupling capacitance between the conductor plug 44a connected to the source region 28S of the PMOS transistor 34 and the dummy gate electrode 38a.

In the present embodiment, a decoupling capacitance is formed by using the dummy gate electrode adjacent to the source region, but the dummy gate electrode is not essential. A decoupling capacitance may be formed by suitably using a pattern adjacent to the source region.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a first device region formed in a semiconductor substrate and defined by a device isolation region;
a first transistor of a first conduction type including a first gate electrode formed over the first device region, a first source region formed in the first device region on a first side of the first gate electrode, and a first drain region formed in the first device region on a second side of the first gate electrode;
a first pattern formed over the device isolation region on the first side of the first gate electrode in parallel with the first gate electrode;
an insulation layer formed over the semiconductor substrate, covering the first transistor and the first pattern; and
a first conductor plug buried in a first contact hole down to the first source region,
wherein the first conductor plug being electrically connected to one of a ground line and a power source line, and
the first pattern being electrically connected to the other of the ground line and the power source line.

2. A semiconductor device according to claim 1, which further comprises:
a second pattern formed in parallel with the first gate electrode over the device isolation region on the second side of the first gate electrode; and
a second conductor plug buried in a second contact hole down to the first drain region, wherein
the second conductor plug is electrically connected to a signal line, and
the second pattern is electrically floating.

3. A semiconductor device according to claim 2, which further comprises:
a second device region formed on the second side of the second pattern and defined by the device isolation region;
a second transistor of the first conduction type including a second gate electrode formed over the second device region in parallel with the second pattern, a second drain region formed in the second device region on the first side of the second gate electrode, and a second source region formed in the second device region on the second side of the second gate electrode;
a third pattern formed over the device isolation region on the second side of the second gate electrode in parallel with the second gate electrode; and
a third conductor plug buried in a third contact hole down to the second source region, wherein
the third conductor plug is electrically connected to one of the ground line and the power source line, and
the third pattern is electrically connected to the other of the ground line and the power source line.

4. A semiconductor device according to claim 2, further comprising:
a second device region formed on the second side of the second pattern and defined by the device isolation region;
a second transistor of a second conduction type opposite to the first conduction type including a second gate electrode formed over the second device region in parallel with the second pattern, a second drain region formed in the second device region on the first side of the second gate electrode, and a second source region formed in the second device region on the second side of the second gate electrode;
a third pattern formed over the device isolation region on the second side of the second gate electrode and formed in parallel with the second gate electrode;
a third conductor plug buried in a third contact hole down to the second source region, wherein
the third conductor plug is electrically connected to said the other of the ground line and the power source line, and
the third pattern is electrically connected to said one of the ground line and the power source line.

5. A semiconductor device according to claim 1, which further comprises:
a second device region formed spaced from the first device region in the longitudinal direction of the first gate electrode and defined by the device isolation region;
a second transistor of a second conduction type opposite to the first conduction type including a second gate electrode formed over the second device region, a second drain region formed in the second device region on the first side of the second gate electrode, and a second source region formed in the second device region on the second side of the second gate electrode;
a second pattern formed over the device isolation region on the second side of the second gate electrode in parallel with the second gate electrode; and
a second conductor plug buried in a second contact hole down to the second source region, wherein
the second conductor plug is electrically connected to said the other of the ground line and the power source line, and
the second pattern is electrically connected to said one of the ground line and the power source line.

6. A semiconductor device according to claim 5, further comprising:
a third pattern formed over the device isolation region on the second side of the first gate electrode in parallel with the first gate electrode;
a fourth pattern formed over the device isolation region on the first side of the second gate electrode in parallel with the second gate electrode;
a third conductor plug buried in a third contact hole down to the first drain region, and
a fourth conductor plug buried in a fourth contact hole down to the second drain region, wherein
the third pattern and the fourth pattern are electrically floating.

7. A semiconductor device according to claim 6, further comprising:
a third device region formed on the second side of the third pattern and defined by the device isolation region;
a third transistor of the first conduction type including a third gate electrode formed over the third device region in parallel with the third pattern, a third drain region formed in the third device region on the first side of the third gate electrode and a third source region formed in the third device region on the second side of the third gate electrode;
a fifth pattern formed over the device isolation region on the second side of the third gate electrode in parallel with the third gate electrode; and
a fifth conductor plug buried in a fifth contact hole down to the third source region, wherein
the fifth conductor plug is electrically connected to said one of the ground line and the power source line, and
the fifth pattern is electrically connected to said the other of the ground line and the power source line.

8. A semiconductor device according to claim 7, further comprising:
a fourth device region formed spaced from the third device region in the longitudinal direction of the third gate electrode and defined by the device isolation region;
a fourth transistor of the second conduction type including a fourth gate electrode formed over the fourth device region, a fourth source region formed in the fourth device region on the first side of the fourth gate electrode, and a fourth drain region formed in the fourth device region on the second side of the fourth gate electrode;
a sixth pattern formed over the device isolation region on the second side of the fourth gate electrode in parallel with the fourth gate electrode; and
a fourth conductor plug buried in a fourth contact hole down to the fourth source region, wherein
the fourth conductor plug is electrically connected to said the other of the ground line and the power source line, and
the sixth pattern is electrically floating.

9. A semiconductor device according to claim 5, wherein
the first gate electrode is a part of a first gate interconnection crossing the first device region and the second device region,
the second gate electrode is another part of the first gate interconnection,
the third pattern is positioned on an extended line of the second pattern, and
the fourth pattern is positioned on an extended line of the first pattern.

10. A semiconductor device according to claim 8, wherein
the third gate electrode is a part of a second gate interconnection crossing the third device region and the fourth device region,
the fourth gate electrode is another part of the second gate interconnection, and
the sixth pattern is positioned on an extended line of the fifth pattern.

11. A semiconductor device according to claim 1, wherein
the first transistor is an N-channel type transistor,
the first conductor plug is electrically connected to the ground line, and
the first pattern is electrically connected to the power source line.

12. A semiconductor device according to claim 1, wherein
the first transistor is a P-channel type transistor,
the first conductor plug is electrically connected to the power source line, and
the first pattern is electrically connected to the ground line.
